(19) United States
(12) Patent Application Publication
(10) Pub. No.: US 2007/0111029 A1
(43) Pub. Date: May 17, 2007

(54) FLUORENE COMPOUND AND ORGANIC LIGHT-EMITTING DEVICE

(75) Inventors: NAOKI YAMADA, Tokyo (JP); AKIHITO SAITOH, YOKOHAMA-SHI (JP); KEIJI OKINAKA, KAWASAKI-SHI (JP); MASATAKA YASHIMA, TOKYO (JP); AKIHIRO SENOO, KAWASAKI-SHI (JP); KAZUNORI UENO, EBINA-SHI (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 11/554,142

(22) Filed: Oct. 30, 2006

(30) Foreign Application Priority Data
Jul. 7, 2006 (JP) 2006-188155(PAT.)
Nov. 1, 2005 (JP) 2005-317935(PAT.)

(51) Int. Cl. H01L 51/54; C09K 11/06

(52) U.S. Cl. 428/690; 428/917; 313/504; 313/506; 257/E51.049; 257/E51.051; 564/427; 564/433; 564/429

(57) ABSTRACT

The organic light-emitting device capable of emitting light with remarkably high efficiency and luminance by using a fluorene compound having substituents is provided, and at least one layer among the organic compound layers in the device contains a first compound and a second compound, and the first compound is a fluorene compound represented by the following general formula (III) and the second compound is a compound represented by the following general formula (IV).

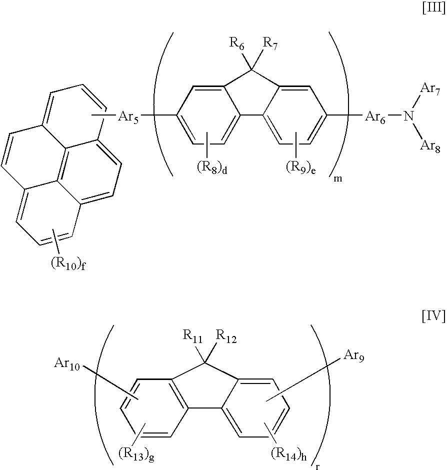

### BACKGROUND OF THE INVENTION

1. Field of the Invention

The present invention relates to novel organic compounds and an organic light-emitting device.

2. Description of the Related Art

An organic light-emitting device is a device in which a thin film containing a fluorescent organic compound or phosphorescent organic compound is sandwiched between an anode and a cathode. The device utilizes light emitted when excitons of the fluorescent compound or phosphorescent compound generated by injecting electrons and holes from the respective electrodes to the fluorescent compound or phosphorescent compound are returned to a ground state.

Recent progress of the organic light-emitting device is noticeable and it is possible to realize a thin and light-weight light-emitting device allowing a high luminance at a low applied voltage, variety of emission wavelength, high-speed responsiveness, thus suggesting possibilities of application to various uses.

However, further improved performances such as light emission with high luminance or high conversion efficiency are required. In addition, there are many accompanied problems in terms of durability such as change with the elapse of time due to use for a long time, and degradation due to an ambient gas containing oxygen or humidity. Moreover, when application for full-color displays or the like is considered, it is necessary to realize emission of blue, green and red lights with good color purities, but solution on these problems has been insufficiently solved yet.

Japanese Patent Application Laid-Open No. 2002-50481 discloses that materials of fluorene-substituted benzene ring provide a device with good emission characteristics and good durability, however concrete description on emission efficiency and durability life is not found.

Further, Japanese Patent Application Laid-Open No. 2002-324678 discloses that materials of pyrene-substituted benzene ring provide a device with good emission characteristics and good durability, however external quantum efficiency is low and concrete description on endurance time is not found.

### SUMMARY OF THE INVENTION

An object of the present invention is to provide a fluorene compound having substituents and to provide an organic light-emitting device capable of emitting light with very high efficiency and luminance by using the fluorene compound. Another object of the present invention is to provide an organic light-emitting device having extremely high durability. Further object of the present invention is to provide an organic light-emitting device which can be easily produced with a relatively low cost.

The fluorene compound of the present invention is represented by the following general formula (I):

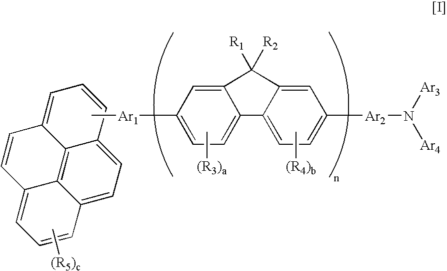

wherein R₁ to R₅ represent a substituted or unsubstituted alkyl group, aralkyl group, aryl group, heterocyclic group, amino group or cyano group, or a halogen atom; R₁ to R₅ may be the same or different; Ar₁ and Ar₂ represent a substituted or unsubstituted alkylene group, aralkylene group, arylene group or heterocyclic group or may be a direct single bond; Ar₁ and Ar₂ may be the same or different; Ar₃ and Ar₄ represent a substituted or unsubstituted phenyl group having at least one alkyl group having 2 or more carbon atoms at position 4; Ar₃ and Ar₄ may be the same or different; n represents an integer from 1 to 10; a and b represent an integer from 0 to 3; c represents an integer from 0 to 9; when a, b and c are an integer of 2 or more, each R₃, each R₄ and each R₅ may be the same or different; and when n is 2 or more, each R₁, each R₂, each R₃ and each R₄ on different fluorene groups may be the same or different.

The organic light-emitting device of the present invention includes: a pair of electrodes consisting of an anode and a cathode, and one or more layers containing an organic compound, sandwiched between the pair of electrodes, wherein at least one layer among the layers containing the organic compound contains at least one kind of the fluorene compound represented by the above general formula (I).

Further, the organic light-emitting device of the present invention includes: a pair of electrodes consisting of an anode and a cathode, and one or more organic compound layers containing an organic compound, sandwiched between the pair of electrodes, wherein at least one layer among the organic compound layers contains a first compound and a second compound, and the first compound is at least one kind of fluorene compounds represented by the following general formula (III) and the second compound is at least one kind of compounds represented by the following general formula (IV).

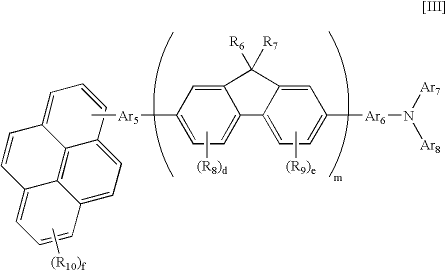

wherein R₆ to R₁₀ represent a substituted or unsubstituted alkyl group, aralkyl group, aryl group, heterocyclic group, amino group or cyano group, or a halogen atom; R₆ to R₁₀ may be the same or different; Ar₅ and Ar₆ represent a substituted or unsubstituted alkylene group, aralkylene group, arylene group or heterocyclic group or may be a direct single bond; Ar₅ and Ar₆ may be the same or different; Ar₇ and Ar₈ represent a substituted or unsubstituted alkyl group, aralkyl group, aryl group or heterocyclic group; Ar₇ and Ar₈ may be the same or different and may be linked together to form a ring; m represents an integer from 1 to 10; d and e represent an integer from 0 to 3; f represents an integer from 0 to 9; when d, e and f are an integer of 2 or more, each R₈, each R₉ and each R₁₀ may be the same or different; and when m is 2 or more, each R₆, each R₇, each R₈ and each R₉ on different fluorene groups may be the same or different.

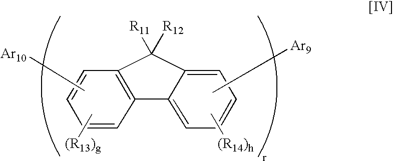

wherein R₁₁ and R₁₂ represent a hydrogen atom, an alkyl group, a substituted or unsubstituted aralkyl group, a substituted or unsubstituted aryl group, or a substituted or unsubstituted heterocyclic group; R₁₁ and R₁₂ may be the same or different; R₁₃ and R₁₄ represent a deuterium atom, an alkyl group, a substituted or unsubstituted aralkyl group, a substituted or unsubstituted aryl group, a substituted or a unsubstituted heterocyclic group, a substituted amino group, a cyano group, or a halogen atom; R₁₃ and R₁₄ may be the same or different; Ar₉ and Ar₁₀ represent a substituted or unsubstituted pyrene; Ar₉ and Ar₁₀ may be the same or different; r represents an integer from 1 to 10; g and h represent an integer from 0 to 3; when g and h are an integer of 2 or more, each R₁₃ and each R₁₄ may be the same or different; and when r is 2 or more, each R₁₁, each R₁₂, each R₁₃ and each R₁₄ on different fluorene groups may be the same or different.

The organic light-emitting device of the present invention provides highly efficient light emission with a low applied voltage and shows superior durability.

Further features of the present invention will become apparent from the following description of exemplary embodiments with reference to the attached drawings.

### BRIEF DESCRIPTION OF THE DRAWINGS

FIG. 1 is a sectional view showing an example of the organic light-emitting device of the present invention;

FIG. 2 is a sectional view showing another example of the organic light-emitting device of the present invention;

FIG. 3 is a sectional view showing still another example of the organic light-emitting device of the present invention;

FIG. 4 is a sectional view showing a further example of the organic light-emitting device of the present invention; and

FIG. 5 is a sectional view showing a still further example of the organic light-emitting device of the present invention.

### DESCRIPTION OF THE EMBODIMENTS

The present invention will be explained in detail hereinbelow.

In the fluorene compound represented by the general formula (I) of the present invention, Ar₃ and Ar₄ are preferably a 4-tertiary-butylphenyl group.

Ar₁ is preferably a phenylene group or a direct single bond.

A fluorene compound represented by the following general formula (II) is more preferable.

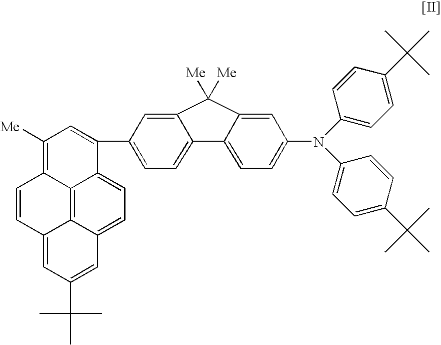

In view of formation of multifunctionality such as highly efficient light emission and efficient electron and hole transport within the same and one molecule, the molecular design of the compound represented by the general formula (I) to (III) of the present invention is performed by linking an amino derivative group and a pyrene derivative group to the fluorene group. In the introduction of the substituted amino group into the fluorene group for expecting highly efficient light emission and hole transport property, adjustment of HOMO/LUMO level of the material can be easily performed by replacing the substituent on the amino group. The molecular design in view of energy level difference of a host material, a hole transport layer and an electron transport layer can be easily achieved by estimating the calculated HOMO/LUMO level. Since the pyrene derivative group exhibits a high quantum yield, improvement in carrier transport property can be expected by the pyrene ring with a high carrier mobility. Further, higher Tg can be achieved by the introduction of the amino group, and materials with good heat stability can be obtained. In addition, when a bulky substituent such as t-butyl group is used as an aryl group which is a substituent on the amino group, high efficient light emission materials with suppressing aggregation between molecules and reducing concentration quenching can be produced.

Examples of substituents on the compounds of the general formula (I) to (IV) are shown hereinbelow.

Examples of the alkyl group are methyl group, ethyl group, n-propyl group, iso-propyl group, n-butyl group, ter-butyl group, sec-butyl group, octyl group, 1-adamantyl group, 2-adamantyl group and the like.

Examples of the alkylene group are methylene group, ethylene group, n-propylene group, n-butylene group and the like.

Examples of the aralkyl group are benzyl group, phenethyl group and the like.

Examples of the aralkylene group include benzylene group, phenethylene group and the like.

Examples of the aryl group are phenyl group, naphthyl group, pentalenyl group, indenyl group, azulenyl group, anthryl group, pyrenyl group, indacenyl group, acenaphthenyl group, phenanthryl group, phenalenyl group, fluoranthenyl group, acephenanthryl group, aceanthryl group, triphenylenyl group, chrysenyl group, naphthacenyl group, perylenyl group, pentacenyl group, biphenyl group, terphenyl group, fluorenyl group and the like.

Examples of the arylene group are phenylene group, naphthylene group, anthrylene group, pyrenylene group, indacenylene group, acenaphthenylene group, phenanthrylene group, phenalenylene group, fluoranthenylene group, acephenanthrylene group, aceanthrylene group, triphenylenylene group, chrysenylene group, biphenylene group, terphenylene group, fluorenylene group and the like.

Examples of the heterocyclic group are thienyl group, pyrrolyl group, pyridyl group, oxazolyl group, oxadiazolyl group, thiazolyl group, thiadiazolyl group, terthienyl group, carbazolyl group, acridinyl group, phenanthrolyl group and the like.

Examples of the bivalent heterocyclic group are thienylene group, pyrrolylene group, pyridylene group, oxazolylene group, oxadiazolylene group, thiazolylene group, thiadiazolylene group, terthienylene group, carbazolylene group, acridinylene group, phenanthrolylene group and the like.

Examples of the substituted amino group are dimethylamino group, diethylamino group, dibenzylamino group, diphenylamino group, ditrylamino group, dianisolylamino group and the like.

Examples of the halogen atom are fluorine, chlorine, bromine and iodine atoms and the like.

Examples of a substituent on which the above-described substituents have are alkyl groups such as methyl group, ethyl group and propyl group; aralkyl groups such as benzyl group and phenethyl group; aryl groups such as phenyl group and biphenyl group; heterocyclic groups such as thienyl group, pyrrolyl group and pyridyl group; silyl groups such as trimethylsilyl group and tert-butyldimethylsilyl group; amino groups such as dimethylamino group, diethylamino group, dibenzylamino group, diphenylamino group, ditrylamino group and dianisolylamino group; alkoxyl groups such as methoxyl group, ethoxyl group, propoxyl group and phenoxyl group; cyano group; and halogen atoms such as fluorine, chlorine, bromine and iodine atoms.

Representative examples of the compounds represented by the general formulae (I) and (III) are shown hereinbelow, but the present invention is not limited to these examples. In the following tables, Ar₁, Ar₂, Ar₃, Ar₄, R₁, R₂, R₃, R₄, R₅, a, b, c and n correspond to Ar₅, Ar₆, Ar₇, Ar₈, R₆, R₇, R₈, R₉, R₁₀, d, e, f and m in the general formula (III), respectively.

TABLE 1

| Com- pound No. | 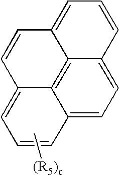 | Ar 1 | 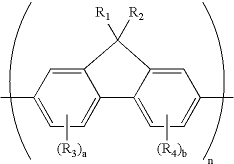 |
|---|---|---|---|
| A-1 | 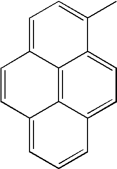 | direct bond | 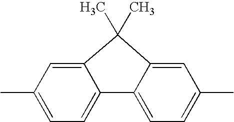 |
| A-2 | 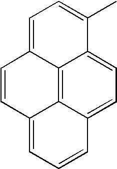 | direct bond | 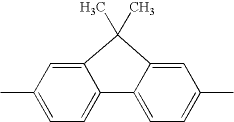 |
| A-3 | 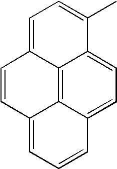 | direct bond | 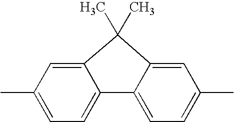 |
| A-4 | 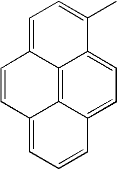 | direct bond | 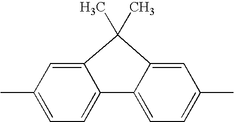 |
| A-5 | 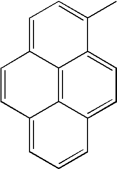 | direct bond | 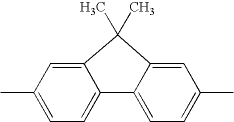 |
| A-6 | 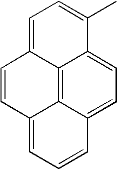 | direct bond | 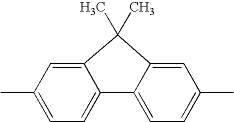 |
| A-7 | 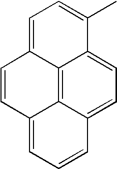 | direct bond | 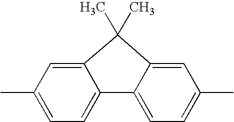 |
| A-8 | 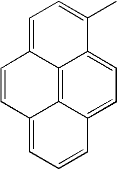 | direct bond | 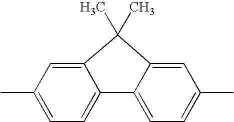 |
| A-9 | 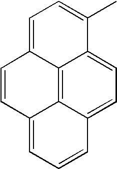 | direct bond | 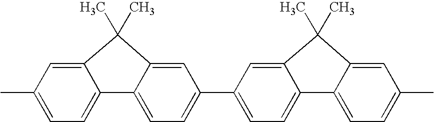 |

| Com- | | | |
|---|---|---|---|
| pound | | | |
| No. | Ar 2 | Ar 3 | Ar 4 |
| A-1 | direct bond | 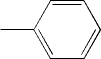 | 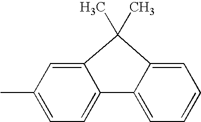 |
| A-2 | direct bond | 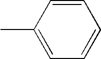 | 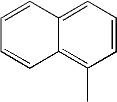 |
| A-3 | direct bond | 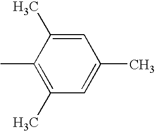 | 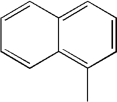 |
| A-4 | direct bond | 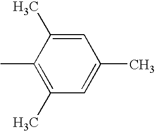 | 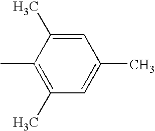 |
| A-5 | direct bond | 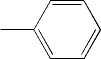 | 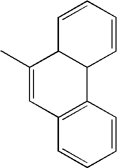 |
| A-6 | direct bond | 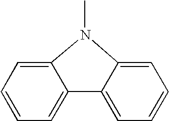 | |
| A-7 | 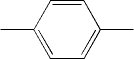 | 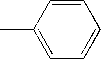 | 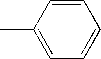 |
| A-8 | 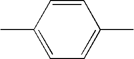 | 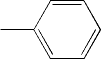 | 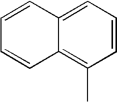 |
| A-9 | 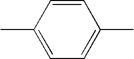 | 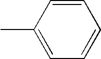 | 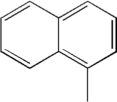 |

TABLE 2

| Com- pound No. | 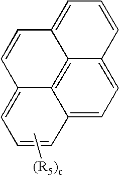 | Ar 1 | 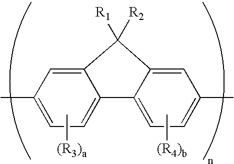 |
|---|---|---|---|
| A-10 | 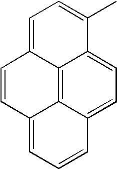 | direct bond | 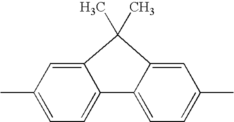 |
| A-11 | 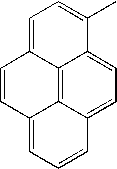 | direct bond | 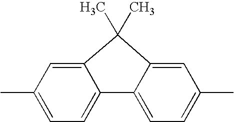 |
| A-12 | 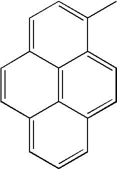 | direct bond | 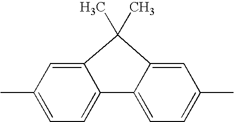 |
| A-13 | 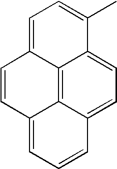 | direct bond | 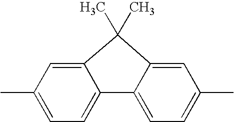 |
| A-14 | 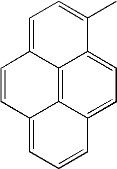 | direct bond | 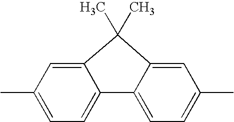 |
| A-15 | 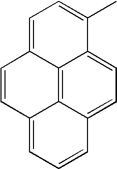 | direct bond | 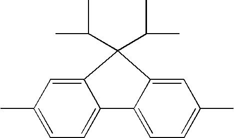 |
| A-16 | 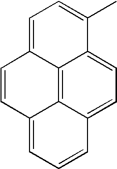 | direct bond | 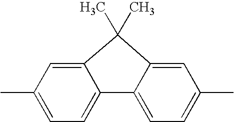 |
| A-17 | 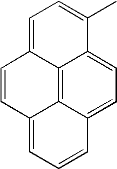 | direct bond | 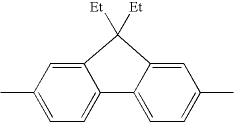 |
| A-18 | 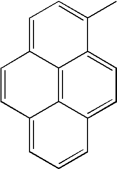 | direct bond | 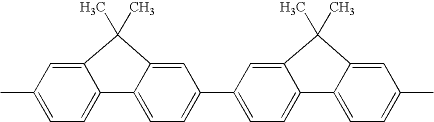 |

| Com- | | | |
|---|---|---|---|
| pound | | | |
| No. | Ar 2 | Ar 3 | Ar 4 |
| A-10 | 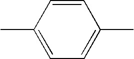 | 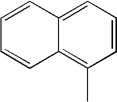 | 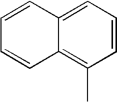 |
| A-11 | 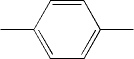 | 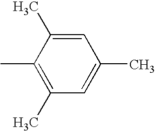 | 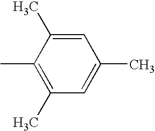 |
| A-12 | 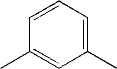 | 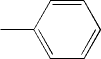 | 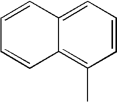 |
| A-13 | 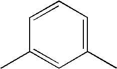 | 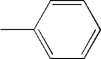 | 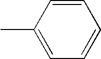 |
| A-14 | 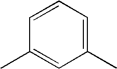 | 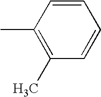 | 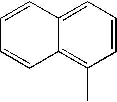 |
| A-15 | 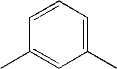 | 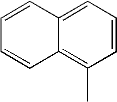 | 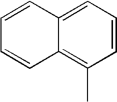 |
| A-16 | 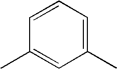 | 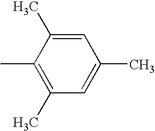 | 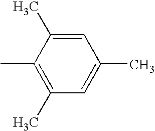 |
| A-17 | 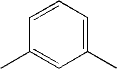 | 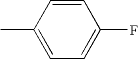 | 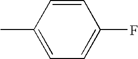 |
| A-18 | 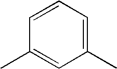 | 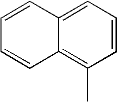 | 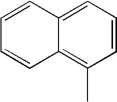 |

TABLE 3

| Com- pound No. | 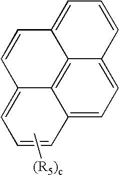 | Ar 1 | 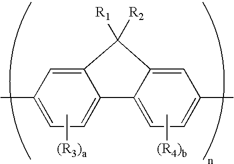 |
|---|---|---|---|
| A-19 | 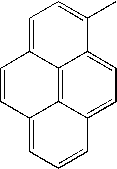 | direct bond | 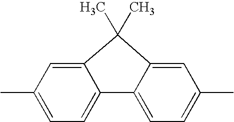 |
| A-20 | 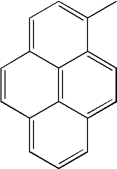 | direct bond | 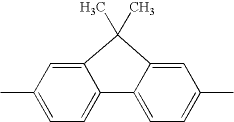 |
| A-21 | 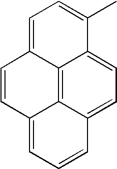 | direct bond | 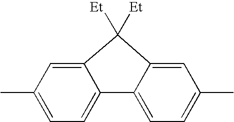 |
| A-22 | 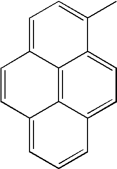 | direct bond | 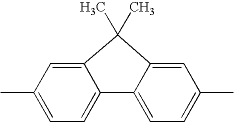 |
| A-23 | 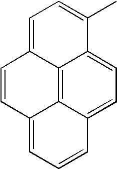 | direct bond | 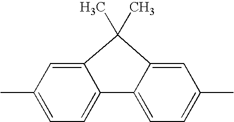 |
| A-24 | 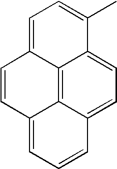 | 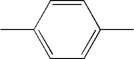 | 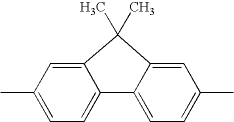 |
| A-25 | 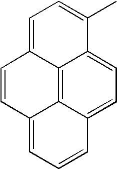 | 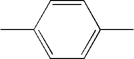 | 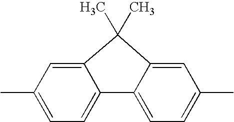 |
| A-26 | 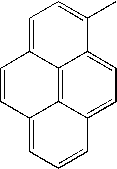 | 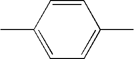 | 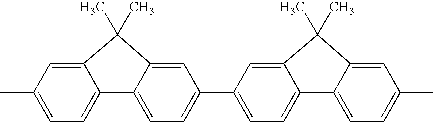 |
| A-27 | 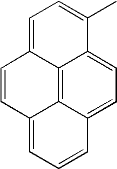 | 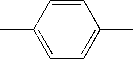 | 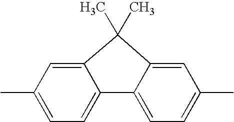 |

| Com- | | | |
|---|---|---|---|
| pound | | | |
| No. | Ar 2 | Ar 3 | Ar 4 |
| A-19 | 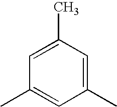 | 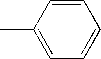 | 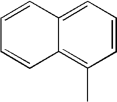 |
| A-20 | 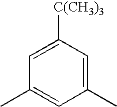 | 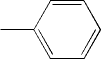 | 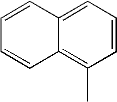 |
| A-21 | 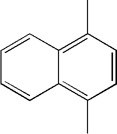 | 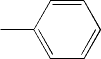 | 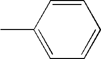 |
| A-22 | 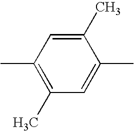 | 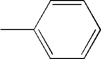 | 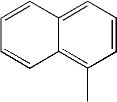 |
| A-23 | 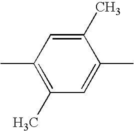 | 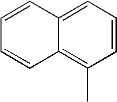 | 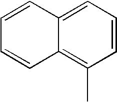 |
| A-24 | 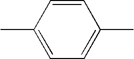 | 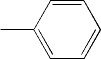 | 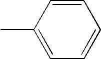 |
| A-25 | 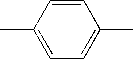 | 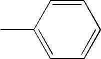 | 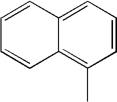 |
| A-26 | 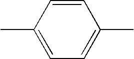 | 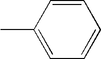 | 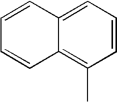 |
| A-27 | 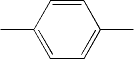 | 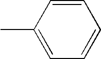 | 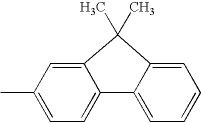 |

TABLE 4

| Com- pound No. | 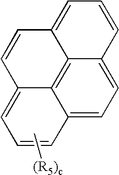 | Ar 1 | 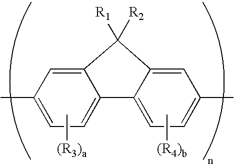 | Ar 2 |
|---|---|---|---|---|
| A-28 | 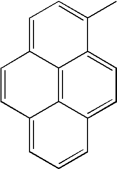 | 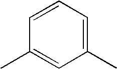 | 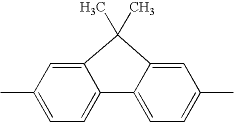 | 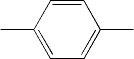 |
| A-29 | 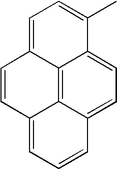 | 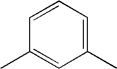 | 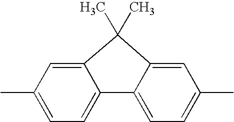 | 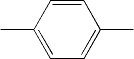 |
| A-30 | 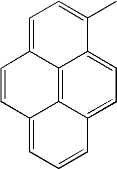 | 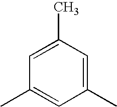 | 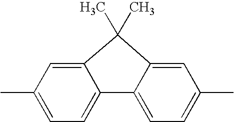 | 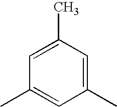 |
| A-31 | 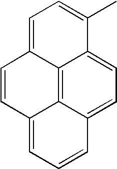 | 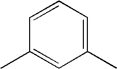 | 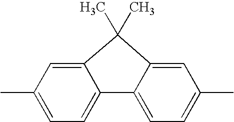 | 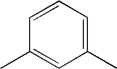 |
| A-32 | 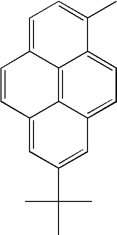 | direct bond | 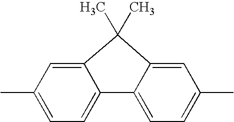 | direct bond |
| A-33 | 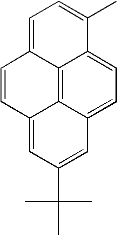 | direct bond | 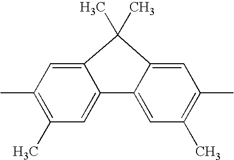 | 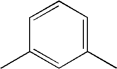 |
| A-34 | 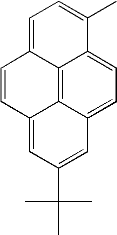 | direct bond | 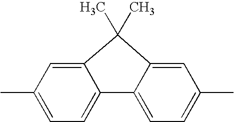 | 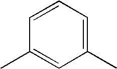 |
| A-35 | 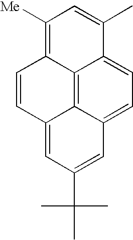 | direct bond | 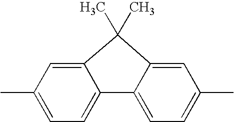 | 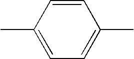 |

| Com- | | |
|---|---|---|
| pound | | |
| No. | Ar 3 | Ar 4 |
| A-28 | 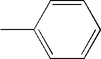 | 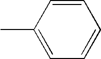 |
| A-29 | 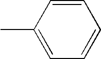 | 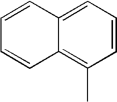 |
| A-30 | 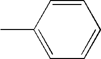 | 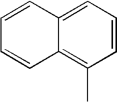 |
| A-31 | 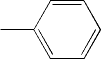 | 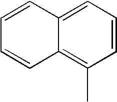 |
| A-32 | 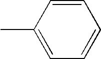 | 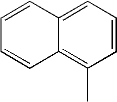 |
| A-33 | 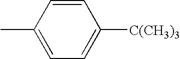 | 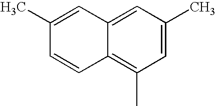 |
| A-34 | 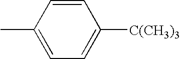 | 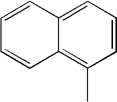 |
| A-35 | 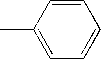 | 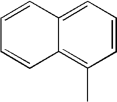 |

TABLE 5

| Com- pound No. | 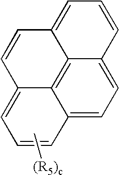 | Ar 1 | 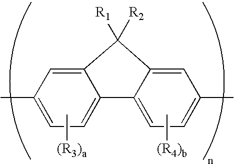 | Ar 2 |
|---|---|---|---|---|
| A-36 | 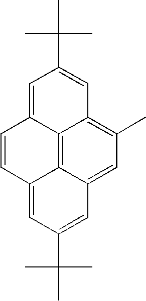 | direct bond | 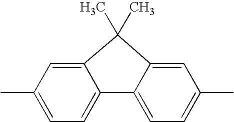 | 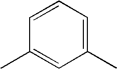 |
| A-37 | 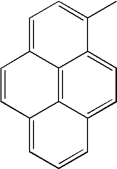 | 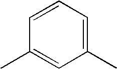 | 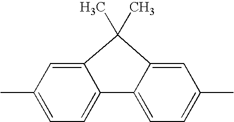 | 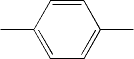 |
| A-38 | 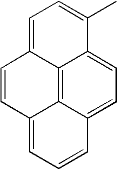 | 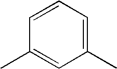 | 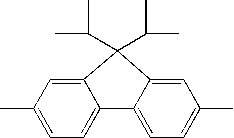 | 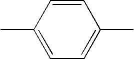 |
| A-39 | 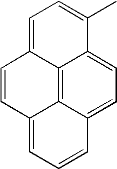 | direct bond | 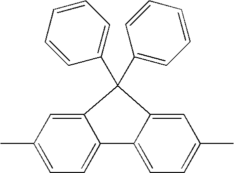 | direct bond |
| A-40 | 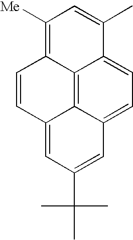 | direct bond | 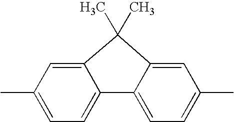 | direct bond |
| A-41 | 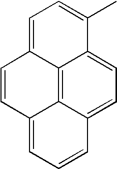 | 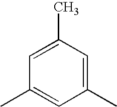 | 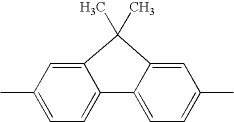 | direct bond |
| A-42 | 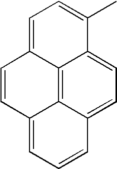 | 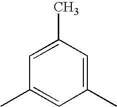 | 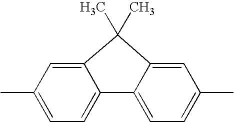 | direct bond |
| A-43 | 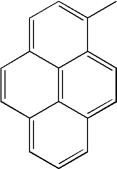 | 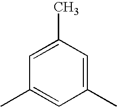 | 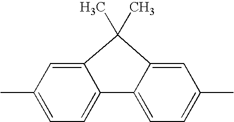 | direct bond |

| Com- | | |
|---|---|---|
| pound | | |
| No. | Ar 3 | Ar 4 |
| A-36 | 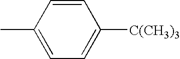 | 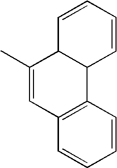 |
| A-37 | 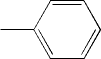 | 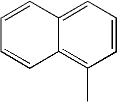 |
| A-38 | 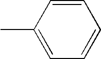 | 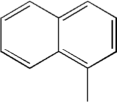 |
| A-39 | 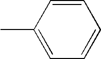 | 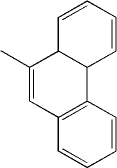 |
| A-40 | 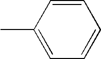 | 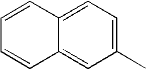 |
| A-41 | 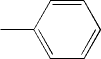 | 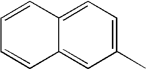 |
| A-42 | 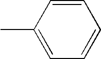 | 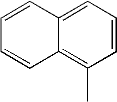 |
| A-43 | 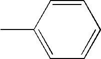 | 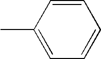 |

TABLE 6

| Com- pound No. | 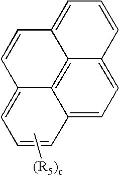 | Ar 1 | 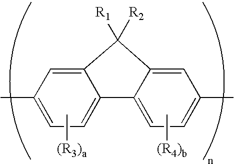 | Ar 2 |
|---|---|---|---|---|
| A-44 | 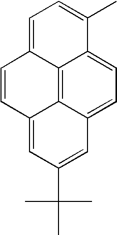 | direct bond | 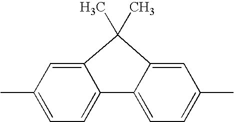 | direct bond |
| A-45 | 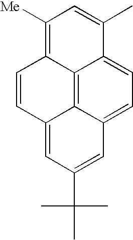 | direct bond | 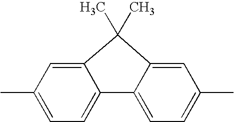 | direct bond |
| A-46 | 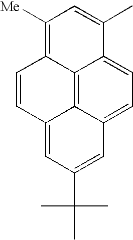 | direct bond | 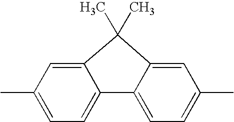 | direct bond |
| A-47 | 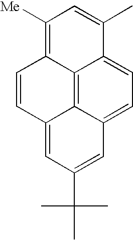 | direct bond | 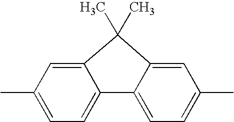 | direct bond |
| A-48 | 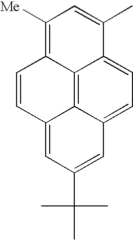 | direct bond | 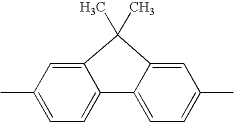 | direct bond |
| A-49 | 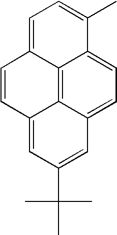 | direct bond | 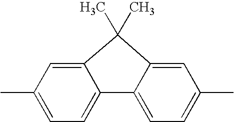 | 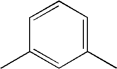 |

| Com- | | |
|---|---|---|
| pound | | |
| No. | Ar 3 | Ar 4 |
| A-44 | 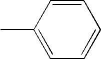 | 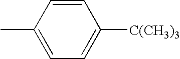 |
| A-45 | 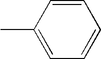 | 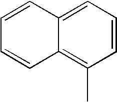 |
| A-46 | 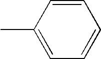 | 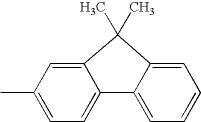 |
| A-47 | 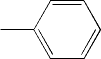 | 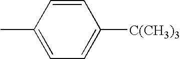 |
| A-48 | 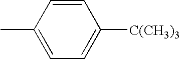 | 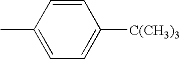 |
| A-49 | 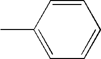 | 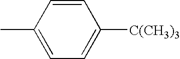 |

TABLE 7

| Com- pound No. | 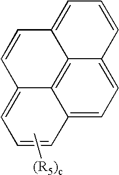 | Ar 1 | 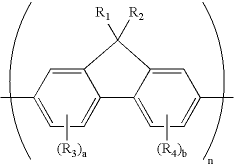 |
|---|---|---|---|
| A-50 | 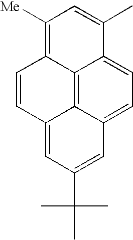 | direct bond | 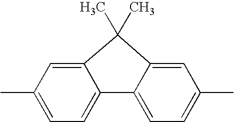 |
| A-51 | 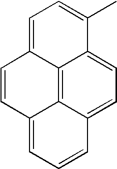 | direct bond | 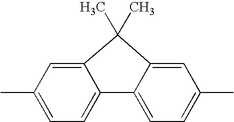 |
| A-52 | 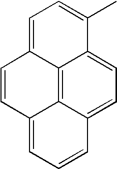 | 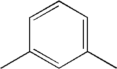 | 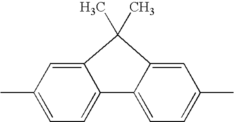 |
| A-53 | 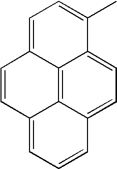 | 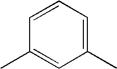 | 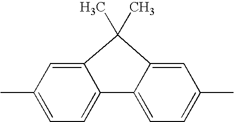 |
| A-54 | 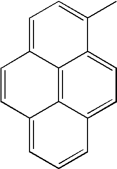 | 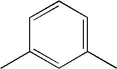 | 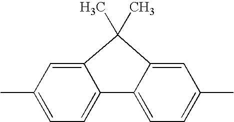 |
| A-55 | 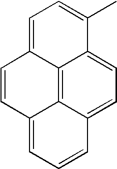 | 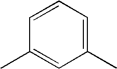 | 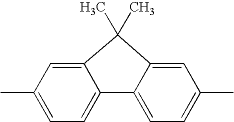 |
| A-56 | 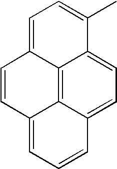 | 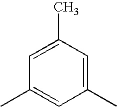 | 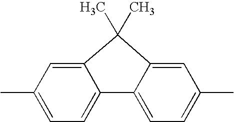 |
| A-57 | 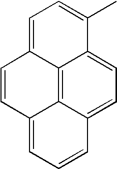 | 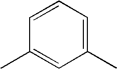 | 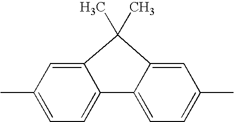 |

| Com- | | | |
|---|---|---|---|
| pound | | | |
| No. | Ar 2 | Ar 3 | Ar 4 |
| A-50 | 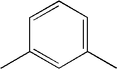 | 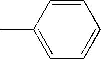 | 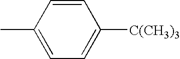 |
| A-51 | 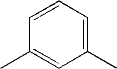 | 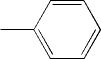 | 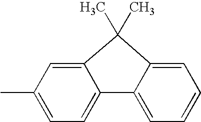 |
| A-52 | direct bond | 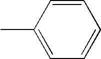 | 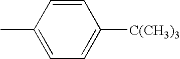 |
| A-53 | direct bond | 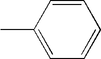 | 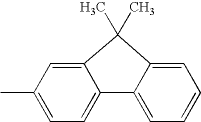 |
| A-54 | direct bond | 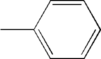 | 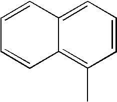 |
| A-55 | direct bond | 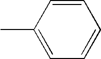 | 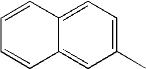 |
| A-56 | direct bond | 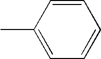 | 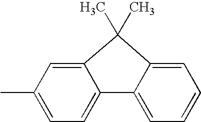 |
| A-57 | 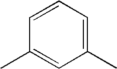 | 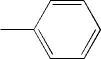 | 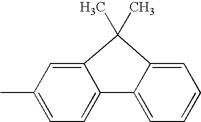 |

TABLE 8

| Com- pound No. | 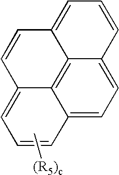 | Ar 1 | 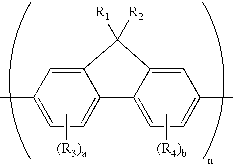 |
|---|---|---|---|
| A-58 | 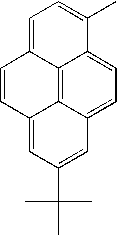 | 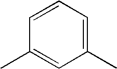 | 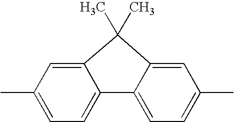 |
| A-59 | 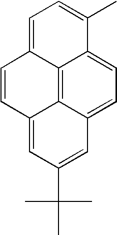 | 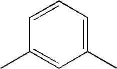 | 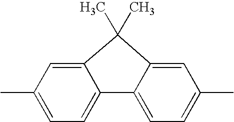 |
| A-60 | 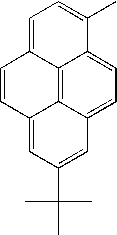 | 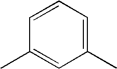 | 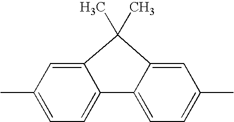 |
| A-61 | 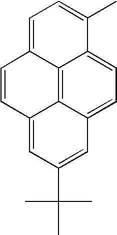 | 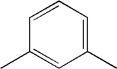 | 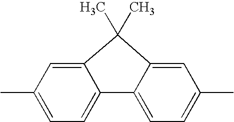 |
| A-62 | 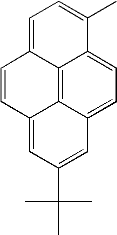 | 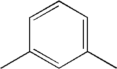 | 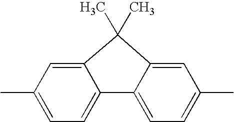 |
| A-63 | 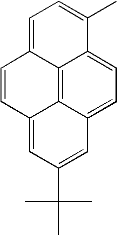 | 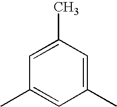 | 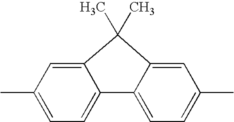 |
| A-64 | 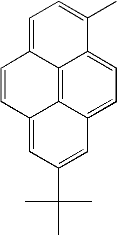 | 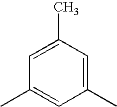 | 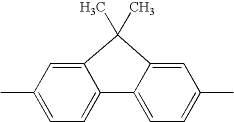 |

| Com- | | | |
|---|---|---|---|
| pound | | | |
| No. | Ar 2 | Ar 3 | Ar 4 |
| A-58 | 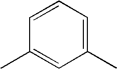 | 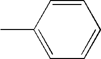 | 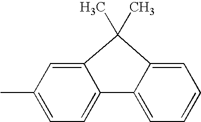 |
| A-59 | direct bond | 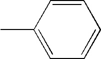 | 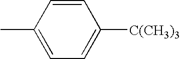 |
| A-60 | direct bond | 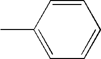 | 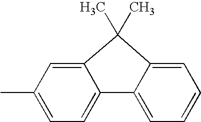 |
| A-61 | direct bond | 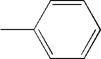 | 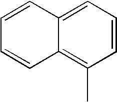 |
| A-62 | direct bond | 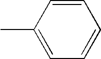 | 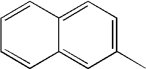 |
| A-63 | direct bond | 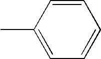 | 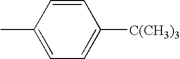 |
| A-64 | direct bond | 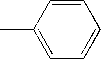 | 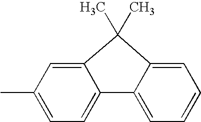 |

TABLE 9

| Com- pound No. | 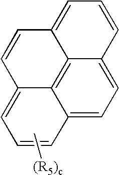 | Ar 1 | 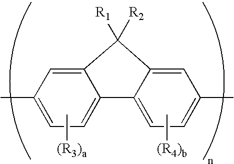 |
|---|---|---|---|
| A-65 | 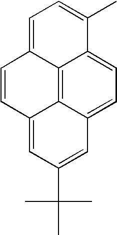 | 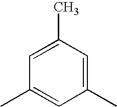 | 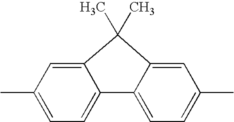 |
| A-66 | 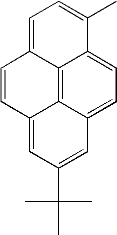 | 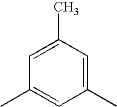 | 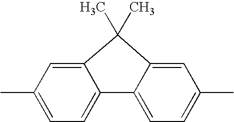 |
| A-67 | 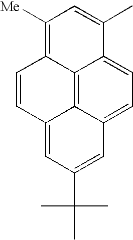 | 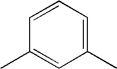 | 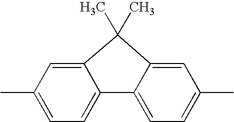 |
| A-68 | 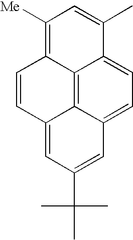 | 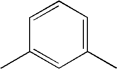 | 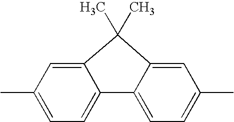 |
| A-69 | 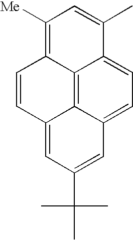 | 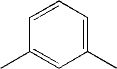 | 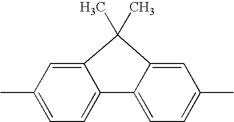 |
| A-70 | 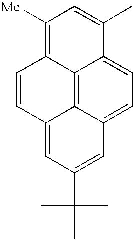 | 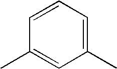 | 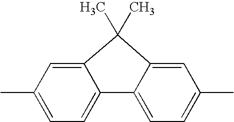 |

| Com- | | | |
|---|---|---|---|
| pound | | | |
| No. | Ar 2 | Ar 3 | Ar 4 |
| A-65 | direct bond | 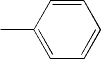 | 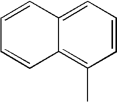 |
| A-66 | direct bond | 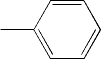 | 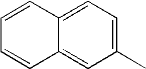 |
| A-67 | direct bond | 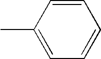 | 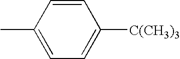 |
| A-68 | direct bond | 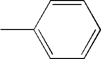 | 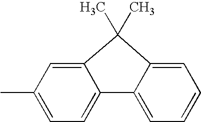 |
| A-69 | direct bond | 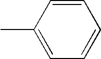 | 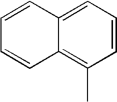 |
| A-70 | | 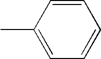 | 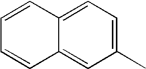 |

TABLE 10

| Com- pound No. | 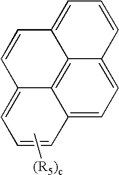 | Ar 1 | 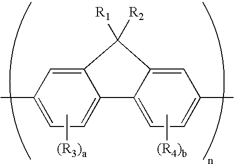 | Ar 2 |
|---|---|---|---|---|
| A-71 | 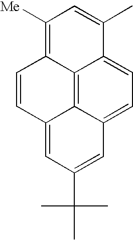 | 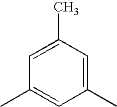 | 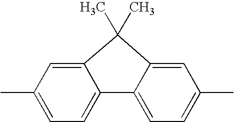 | direct bond |
| A-72 | 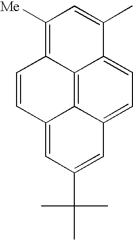 | 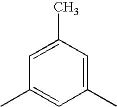 | 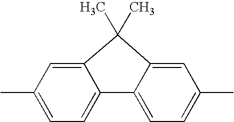 | direct bond |
| A-73 | 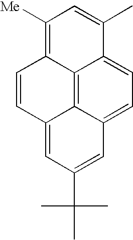 | 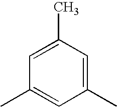 | 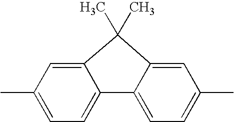 | direct bond |
| A-74 | 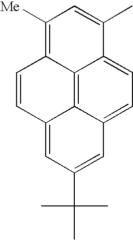 | 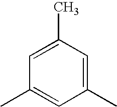 | 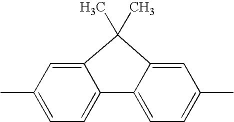 | direct bond |
| A-75 | 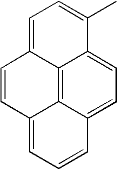 | direct bond | 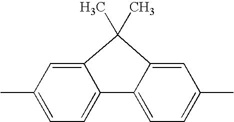 | 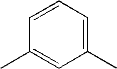 |
| A-76 | 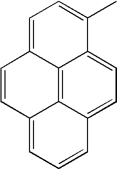 | direct bond | 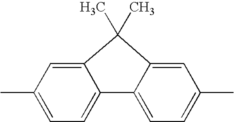 | 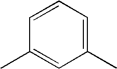 |
| A-77 | 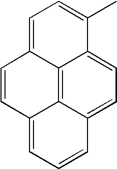 | direct bond | 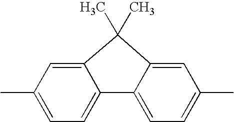 | 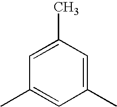 |

| Com- | | |
|---|---|---|
| pound | | |
| No. | Ar 3 | Ar 4 |
| A-71 | 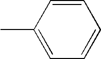 | 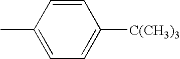 |
| A-72 | 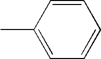 | 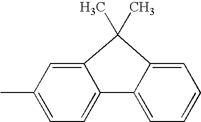 |
| A-73 | 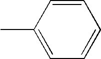 | 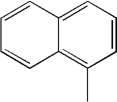 |
| A-74 | 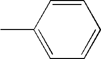 | 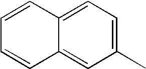 |
| A-75 | 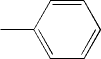 | 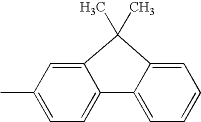 |
| A-76 | 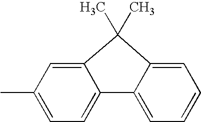 | 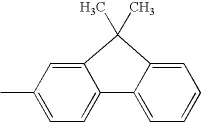 |
| A-77 | 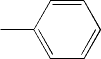 | 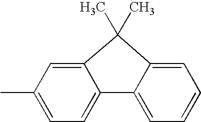 |

TABLE 11

| Compound No. | 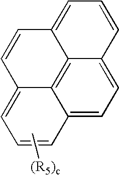 | Ar1 | 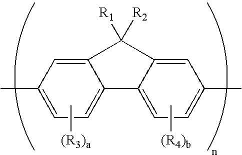 | Ar2 |
|---|---|---|---|---|
| A-78 | 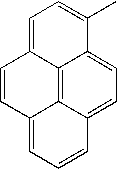 | direct bond | 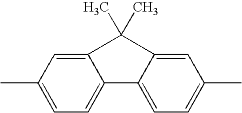 | 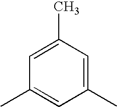 |
| A-79 | 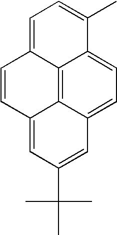 | direct bond | 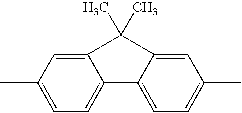 | 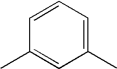 |
| A-80 | 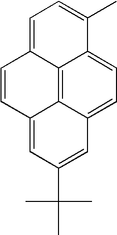 | direct bond | 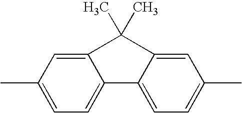 | 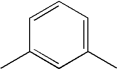 |
| A-81 | 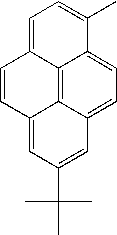 | direct bond | 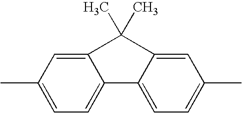 | 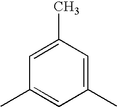 |
| A-82 | 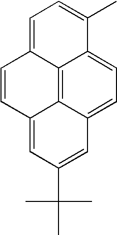 | direct bond | 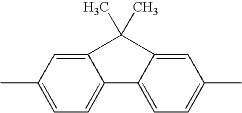 | 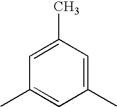 |
| A-83 | 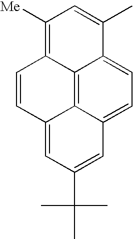 | direct bond | 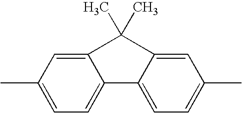 | 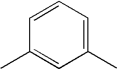 |
| A-84 | 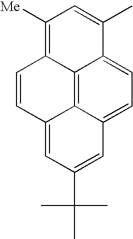 | direct bond | 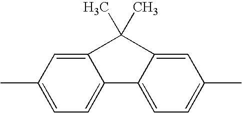 | 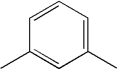 |

| Compound | | |
|---|---|---|
| No. | Ar3 | Ar4 |
| A-78 | 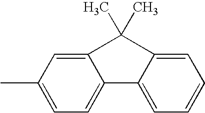 | 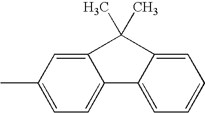 |
| A-79 | 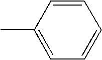 | 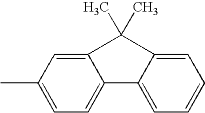 |
| A-80 | 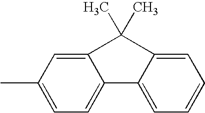 | 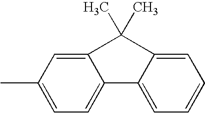 |
| A-81 | 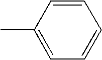 | 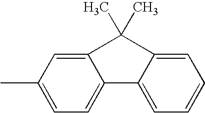 |
| A-82 | 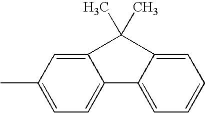 | 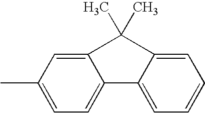 |
| A-83 | 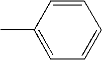 | 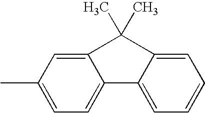 |
| A-84 | 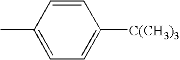 | 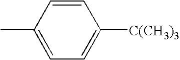 |

TABLE 12

| Compound No. | 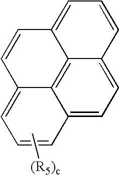 | Ar1 | 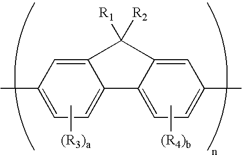 | Ar2 | Ar3 |
|---|---|---|---|---|---|
| A-85 | 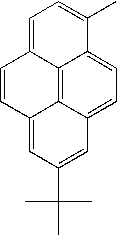 | direct bond | 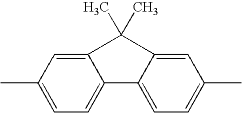 | direct bond | 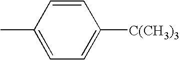 |
| A-86 | 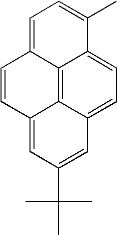 | direct bond | 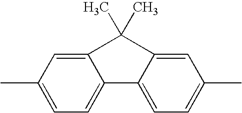 | direct bond | 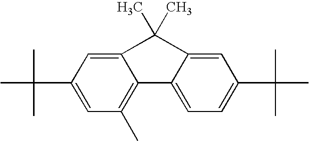 |
| A-87 | 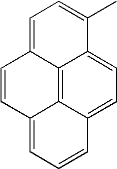 | direct bond | 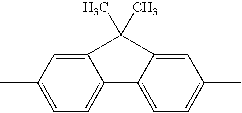 | direct bond | 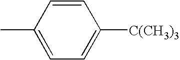 |
| A-88 | 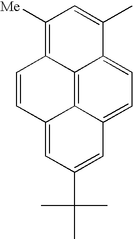 | direct bond | 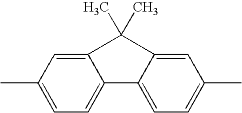 | direct bond | 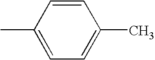 |
| A-89 | 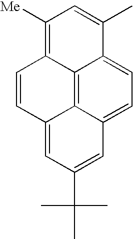 | direct bond | 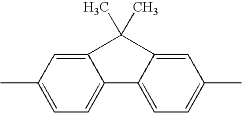 | direct bond | 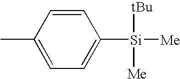 |
| A-90 | 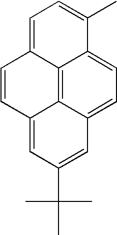 | direct bond | 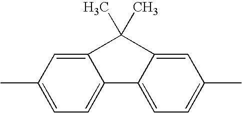 | direct bond | 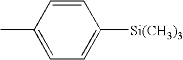 |

| Compound | |
|---|---|
| No. | Ar4 |
| A-85 | 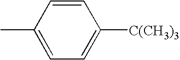 |
| A-86 | 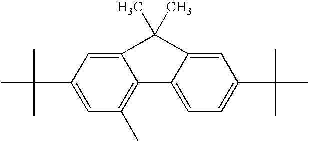 |
| A-87 | 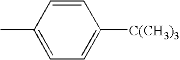 |
| A-88 | 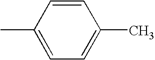 |
| A-89 | 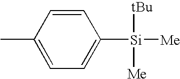 |
| A-90 | 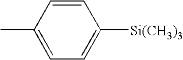 |

Representative examples of the compounds represented by the general formula (IV) are shown hereinbelow, but the present invention is not limited to these examples.

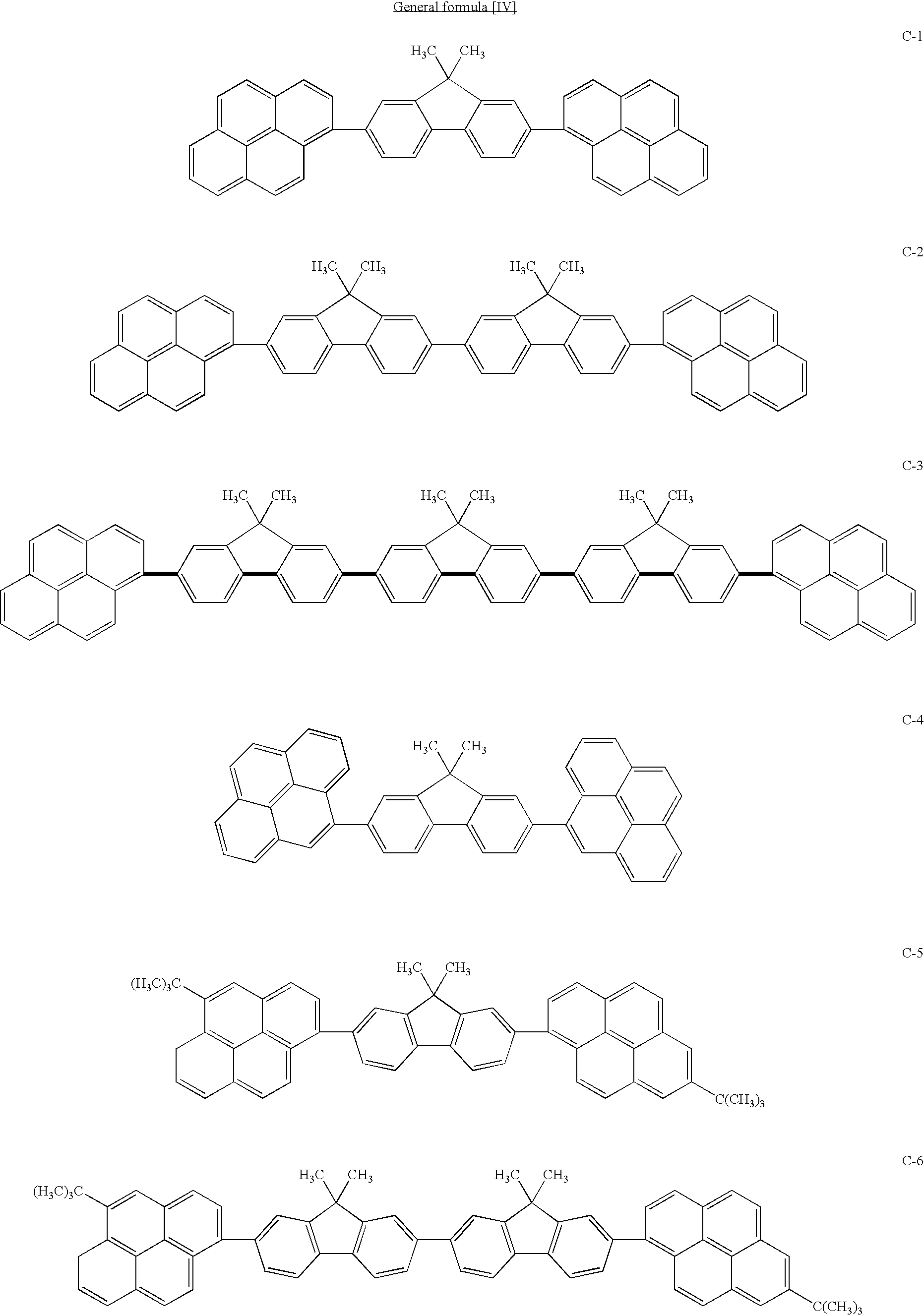

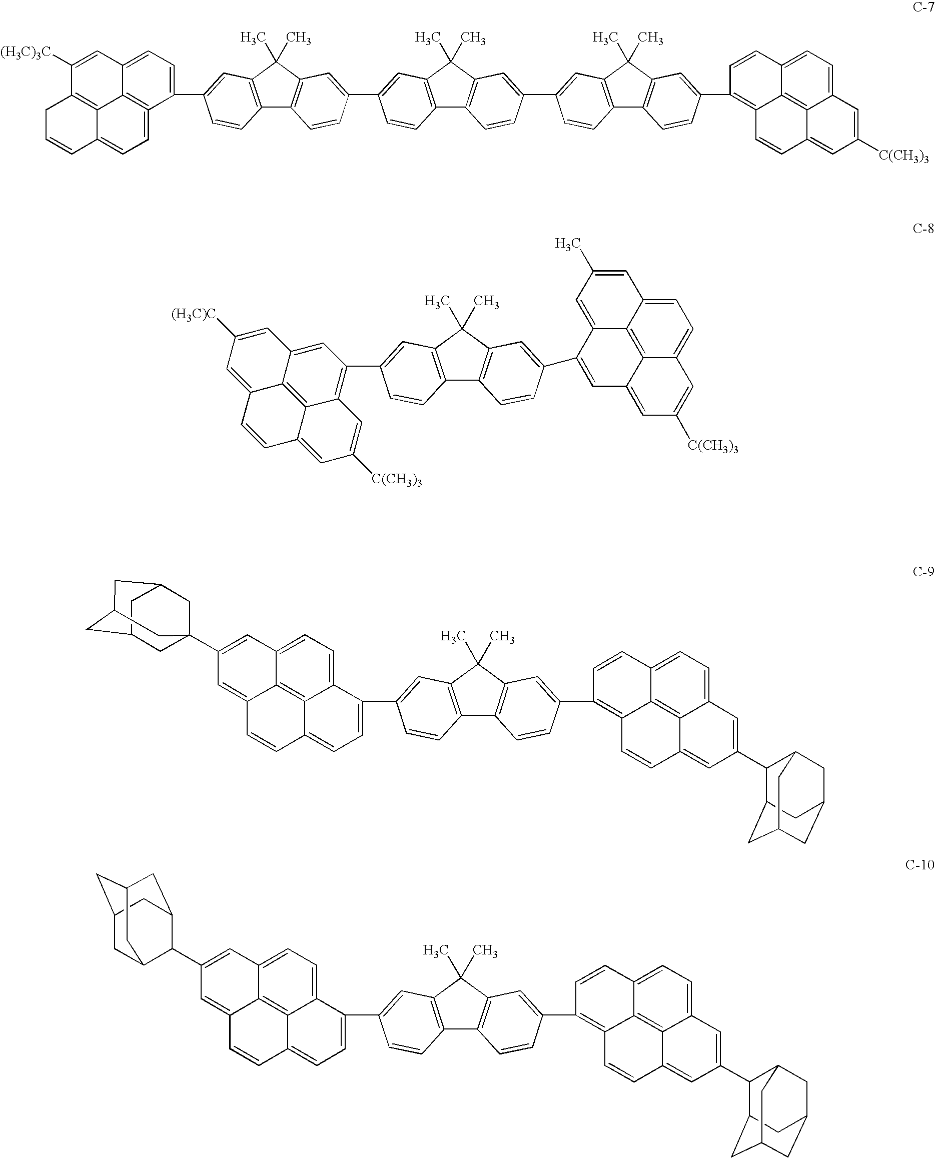

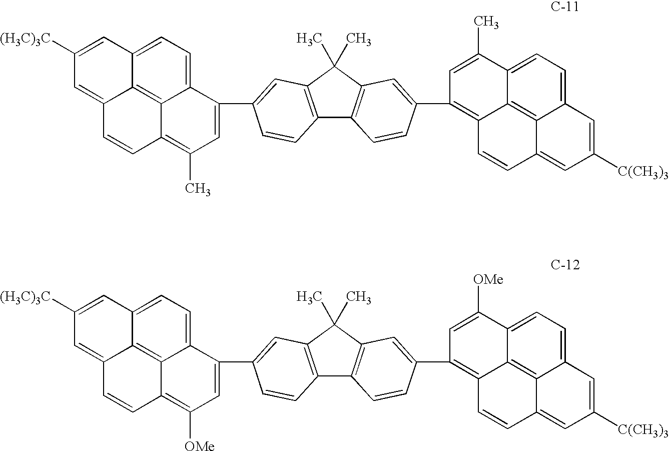

The organic light-emitting device of the present invention will be explained in detail hereinbelow.

An organic light-emitting device of the present invention is an organic light-emitting device composed of a pair of electrodes consisting of an anode and a cathode and one or more layers containing an organic compound, sandwiched between the pair of electrodes. In addition, at least one layer of the layers containing the organic compound contains at least one kind of the fluorene compound represented by the general formula (I).

Another organic light-emitting device of the present invention is an organic light-emitting device composed of a pair of electrodes consisting of an anode and a cathode and the organic compound layers of one or more organic compound layers sandwiched between the pair of electrodes. In addition, at least one layer of the organic compound layers contains at least one kind of the fluorene compound (the first compound) represented by the general formula (III) and at least one kind of the compound (the second compound) represented by the general formula (IV).

The first compound herein is preferably the fluorene compound represented by the general formula (I) more preferably the fluorene compound represented by the general formula (II).

In the organic light-emitting device of the present invention, the layer containing the first compound and the second compound is preferably a light emission layer.

A concentration of a dopant (preferably the first compound) to a host material (preferably the second compound) is 0.01% by weight or more and 80% by weight or less, preferably 1% by weight or more and 50% by weight or less. The dopant material may be contained uniformly or with a concentration gradient in all over the layer consisting of the host material, or may be contained partially in some regions to form the host material layer without containing the dopant material.

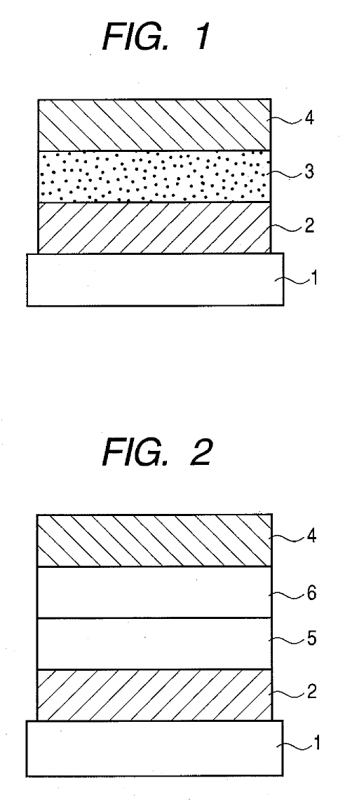

The preferable examples of the organic light-emitting device of the present invention will be shown with reference to FIG. 1 to FIG. 5.

Reference numerals in FIG. 1 to FIG. 5 are explained hereinbelow.

Reference numeral 1 denotes a substrate, 2 an anode, 3 a light emission layer, 4 a cathode, 5 a hole transport layer, 6 an electron transport layer, 7 a hole injection layer, and 8 a hole/exciton blocking layer.

FIG. 1 is a sectional view showing an example of the organic light-emitting device of the present invention. FIG. 1 is the structure including an anode 2, a light emission layer 3 and a cathode 4 disposed sequentially on a substrate 1. The light-emitting device used herein is useful in the case where a single compound having all of the hole transporting ability, the electron transporting ability and the luminescent ability is used, or in the case where the respective compounds having the respective abilities are mixed are mixed and used.

FIG. 2 is a sectional view showing another example of the organic light-emitting device of the present invention. FIG. 2 is the structure including the anode 2, a hole transport layer 5, an electron transport layer 6 and the cathode 4 disposed sequentially on the substrate 1. The light-emitting device in this case is useful in the case where luminescent material having the hole transportability, the electron transportability function or both functions are used in each layer, and the hole transport substance or the electron transport substance without light emission ability is used in combination thereof. Furthermore, in this case, the light emission layer 3 consists of the hole transport layer 5 or the electron transport layer 6.

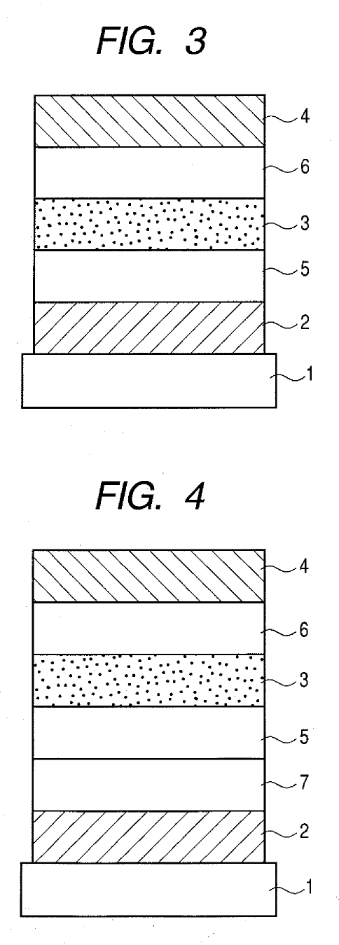

FIG. 3 is a sectional view showing still another example of the organic light-emitting device of the present invention. FIG. 3 is the structure including the anode 2, the hole transport layer 5, the light emission layer 3, the electron transport layer 6 and the cathode 4 disposed sequentially on the substrate 1. In this structure, functions of the carrier transport and the light emission are separated and used by timely combining compounds having a hole transport property, an electron transport property and a light emitting property, respectively, thereby increasing free degree in selection of materials. Since various compounds having different light emission wavelength can be used, diversification of luminescent color becomes possible. Furthermore, improvement of emission efficiency can be made possible by effectively confining each carrier or exciton in the central light emission layer 3.

FIG. 4 is a sectional view showing a further example of the organic light-emitting device of the present invention. FIG. 4 is the structure formed by inserting the hole injection layer 7 onto the side of the anode 2 of the structure of FIG. 3, and is effective for improvement in the adhesiveness between the anode 2 and the hole transport layer 5 or improvement of the hole injection ability, and as a result, is effective for making the voltage of the device lower.

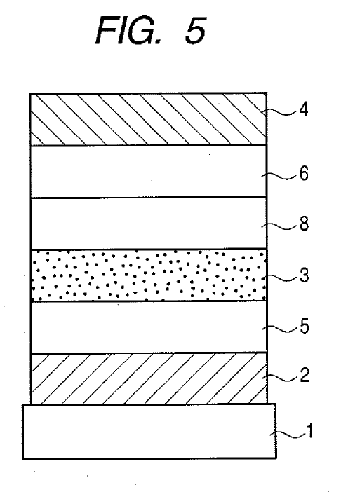

FIG. 5 is a sectional view showing a still further example of the organic light-emitting device of the present invention. FIG. 5 is the structure formed by inserting the layer for blocking the penetration of the hole or the exciton onto the side of the cathode 4 (hole/exciton blocking layer 8), between the light emission layer 3 and the electron transport layer 6 in the structure of FIG. 3. It is an effective structure for improving the emission efficiency by using a very high ionization potential compound as the hole/exciton blocking layer 8.

However, the structure as shown in FIG. 1 to FIG. 5 are the fundamental constructions of the device, and the structure of the organic light-emitting device of the present invention is not limited to them. For example, various structures of the layers can be designed by disposing an insulating layer at an interface between the electrode and the organic layer, disposing an adhesive layer or an interference layer, and forming the hole transport layer composed of two layers having different ionization potentials.

The organic layer using the first compound and the second compound is useful as the light emission layer, the electron transport layer or the hole transport layer. In addition, the layer formed by a vacuum evaporation method and a solution application method is superior in temporal stability because of difficulty of crystallization.

Advantages using both of the first compound and the second compound is as compared with the case of using the first compound alone as follows:

(1) Concentration quenching caused by aggregation of the first compound is suppressed;

(2) Stability of a film is improved by mixing with the second compound; and

(3) Carrier balancing between electrons and holes is easily performed by using two kinds of compounds. As a result, it is effective for a high emission efficiency and a long period life.

Since the first compound and the second compound have a pyrene group as a substituent, dispersibility of the first compound (dopant) to the second compound (host) is good. For that reason, a high effect of suppressing the concentration quenching caused by aggregation of the first compound can be obtained by using two kinds of compounds.

The effect of suppressing the concentration quenching caused by aggregation is higher when the first compound has the general formula (I) wherein Ar₃ and/or Ar₄ are a tertiary-butylphenyl group, and further higher when the first compound is a compound represented by the general formula (II).

Although in the present invention, the first compound and the second compound are used as the constitutional component of the light emission layer, if necessary, known low-molecular-weight and high-molecular-weight compounds having a hole transport property, a luminous property or an electron transport property can also be used together with the first compound and the second compound.

Examples of these compounds are shown hereinbelow.

The hole injection transport material is preferably to readily inject the hole from the anode and to have a high mobility of transporting the injected hole into the light emission layer. Examples of a low-molecular-weight material and a high-molecular-weight material having hole injection transport ability are triarylamine derivatives, phenylenediamine derivatives, triazole derivatives, oxadiazole derivatives, imidazole derivatives, pyrazoline derivatives, pyrazolone derivatives, oxazole derivatives, fluorenone derivatives, hydrazone derivatives, stilbene derivatives, phthalocyanine derivatives, porphyrin derivatives and poly(vinylcarbazole), poly(silylene), poly(thiophene), and other conductive polymers, but the present invention is not limited to these examples. Concrete examples are illustrated hereinbelow.

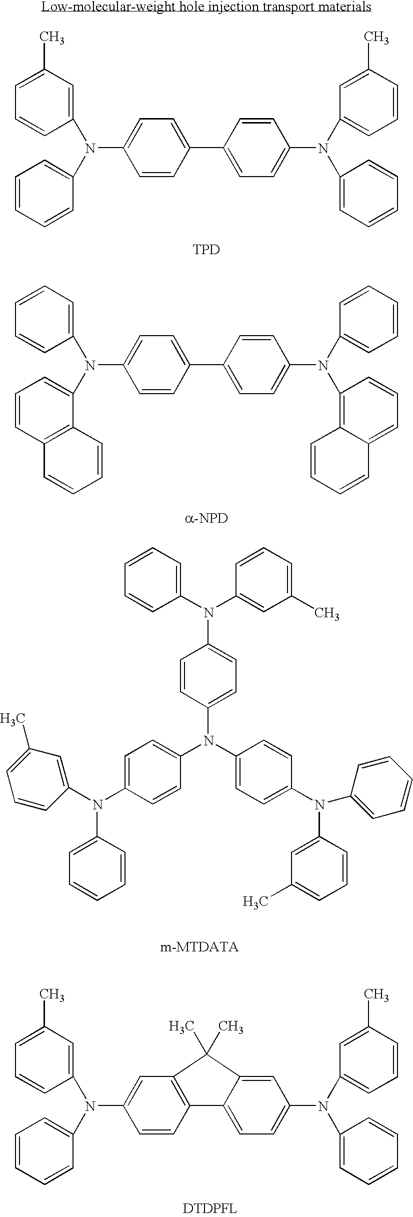

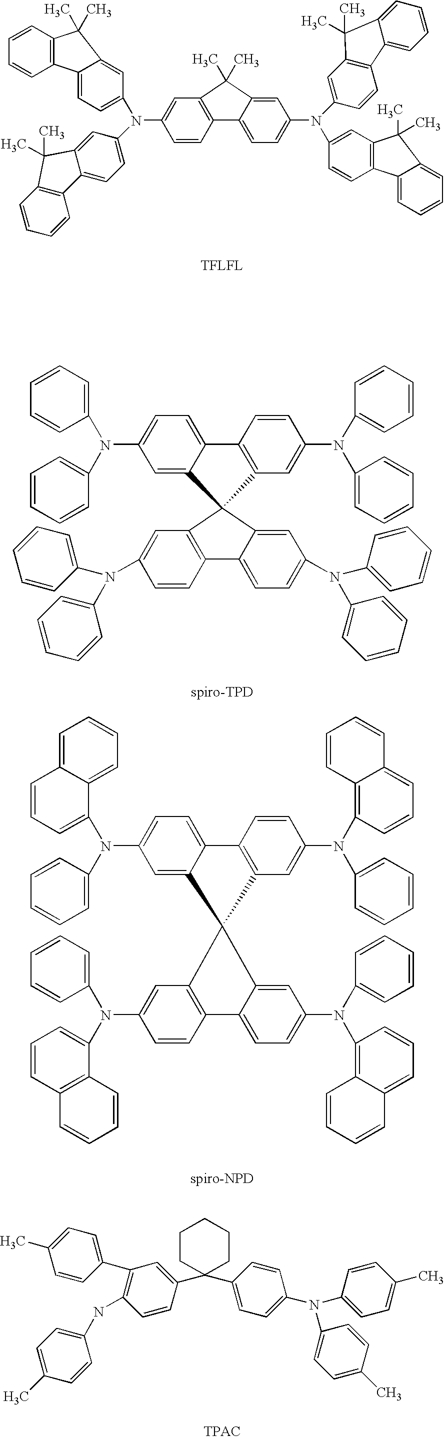

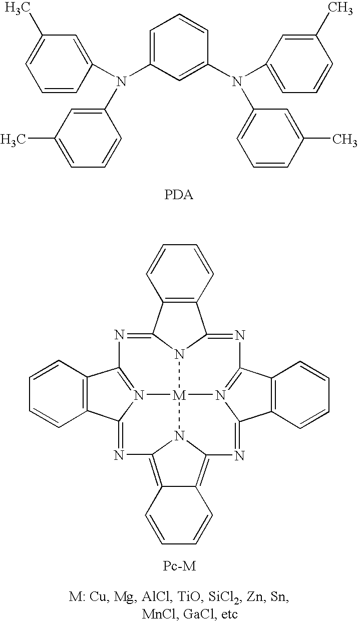

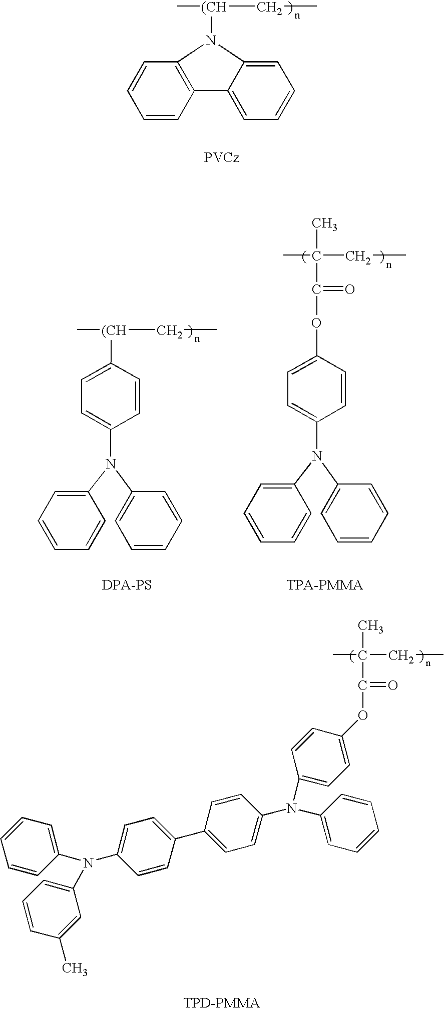

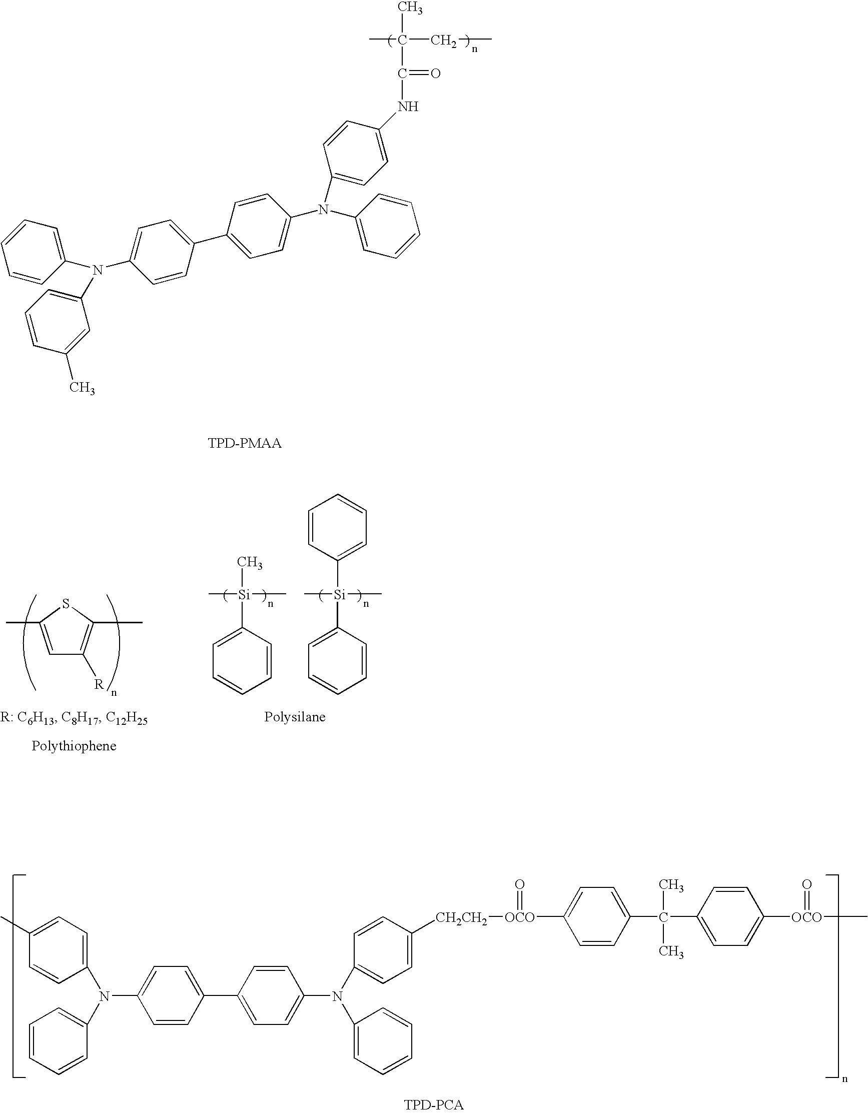

Examples of materials other than the first compound which mainly contribute to the luminescent function are polycyclic condensed aromatic compounds (e.g., naphthalene derivatives, phenanthrene derivatives, fluorene derivatives, pyrene derivatives, tetracene derivatives, coronene derivatives, chrysene derivatives, perylene derivatives, 9,10-diphenylanthracene derivatives, rubrene), quinacridone derivatives, acridone derivatives, coumalin derivatives, pyran derivatives, nile red, pyrazine derivatives, benzoimidazole derivatives, benzothiazole derivatives, benzoxazole derivatives, stilbene derivatives, organic metal complexes (e.g., organic aluminum complexes such as tris(8-quinolinolate)aluminum, organic beryllium complexes) and polymer derivatives such as poly(phenylenevinylene) derivatives, poly(fluorene) derivatives, poly(phenylene) derivatives, poly(thienylenevinylene) derivatives, poly(acetylene) derivatives, and are not limited to these examples. Concrete examples thereof are shown hereinbelow.

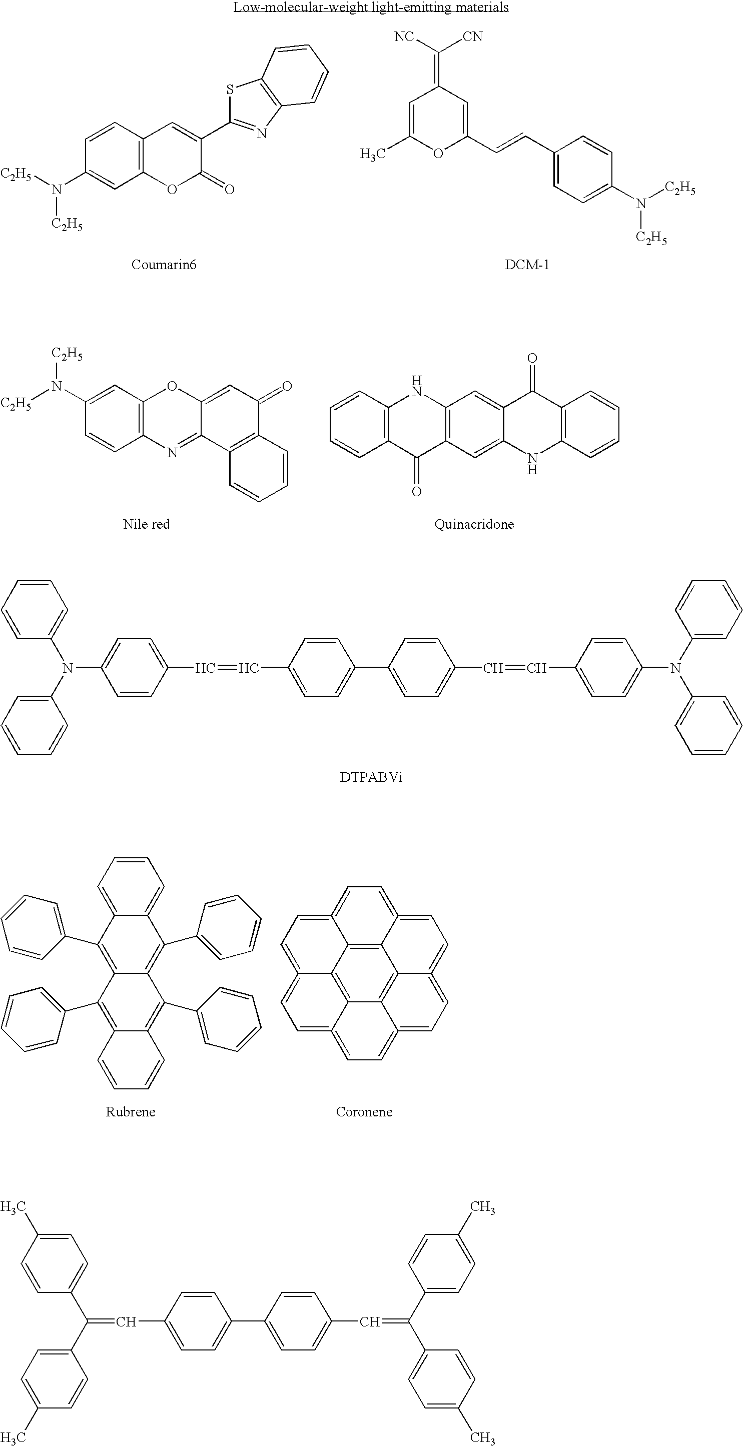

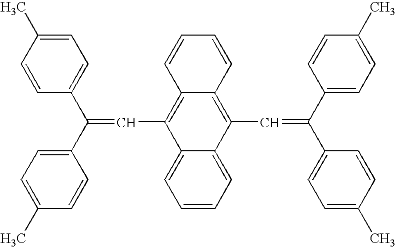

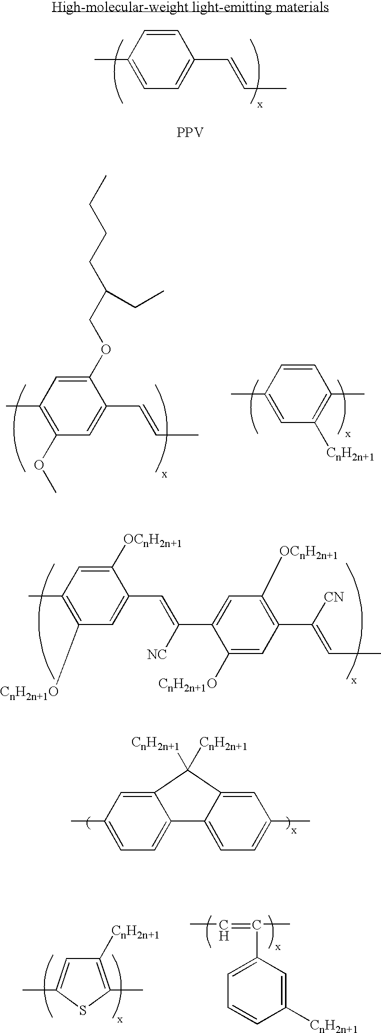

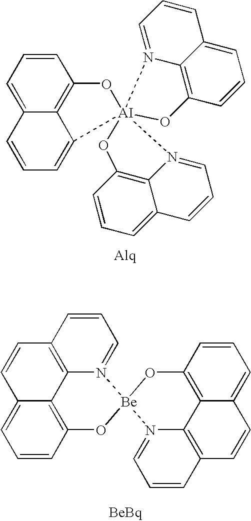

The electron injection transport material can be optionally selected from materials such that it can make injection of electrons from the cathode easy and has the function to transport the injected electrons into the light emission layer, and is selected by considering balance with the carrier mobility of the hole transport material. Examples of the materials having electron injection transport performance are oxadiazole derivatives, oxazole derivatives, thiazole derivatives, thiadiazole derivatives, pyrazine derivatives, triazole derivatives, triazine derivatives, perylene derivatives, quinoline derivatives, quinoxaline derivatives, fluorenone derivatives, anthrone derivatives, phenanethroline derivatives and organic metal complexes, and is not limited to these derivatives. A part of concrete examples will be shown hereinbelow.

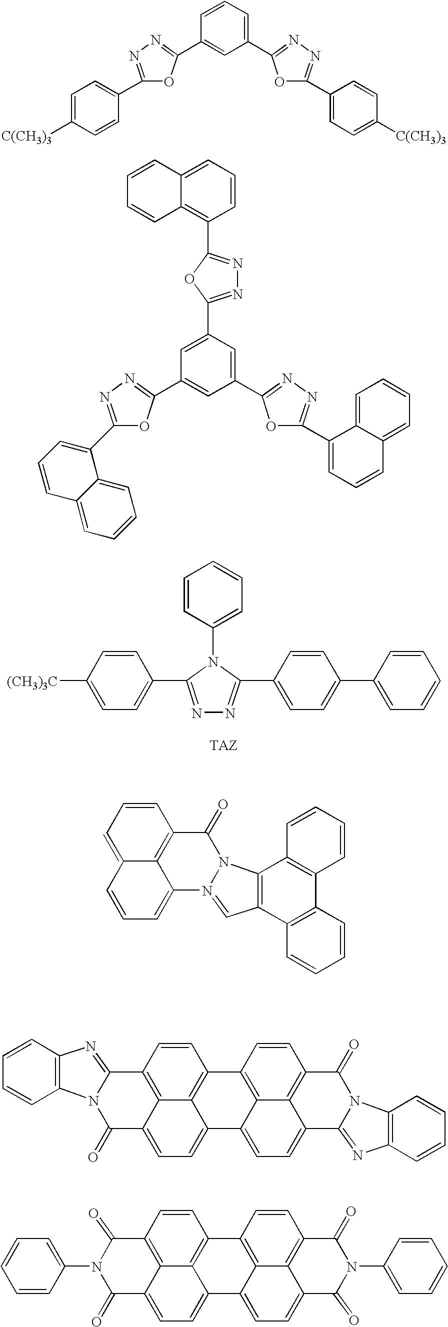

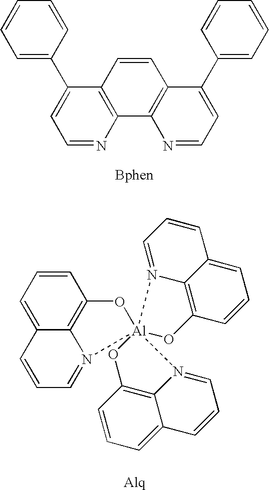

In the organic light-emitting device of the present invention, the layer containing the first compound and the second compound and the layers consisting of other organic compounds are formed as a thin film by a vacuum deposition method, an ionization deposition method, a sputtering technique, a plasma method, etc. Thin film can be formed after dissolving in a suitable solvent, for example, by the known coating method such as a spin coat method, a dipping, a cast coating method, an LB method, an inkjet method, etc. Specifically in the film formation by a coating method, a film can be formed by combining with a proper binder resin.

The binder resin can be optionally selected from various binder resins, for example, poly(vinylcarbazole) resins, polycarbonate resins, polyester resins, polyarylate resins, polystyrene resins, ABS resins, polybutadiene resins, polyurethane resins, acrylic resins, methacrylic resins, butyral resins, poly(vinyl acetal) resins, polyamide resins, polyimide resins, polyethylene resins, polyether sulfon resins, diallylphthalate resins, phenol resins, epoxy resins, silicone resins, polysulfone resins, urea resins, etc. and is not limited to these resins. These resins can be used alone or in combination with one or more resins as copolymers. If necessary, known additives such as a plasticizer, an antioxidant, an ultraviolet and an absorber can be used in combination.

Anode materials may preferably have as large work function as possible, and examples thereof are metals such as gold, platinum, silver, copper, nickel, palladium, cobalt, selenium, vanadium and tungsten; or alloys of these metal; or metal oxides such as tin oxide, zinc oxide, indium oxide, indium tin oxide (ITO), and zinc indium oxide. Further, electroconductive polymers such as polyaniline, polypyrrole, polythiophene, and polyphenylenesulfide, can also be used. The anode materials can be used alone or in combination. In addition, the anode can also have a single layer structure or a multi-layer structure.

Cathode materials may preferably have as small work function as possible and examples thereof are metals such as lithium, sodium, potassium, calcium, magnesium, aluminum, indium, ruthenium, titanium, manganese, yttrium, silver, lead, tin, and chromium, or a plurality of alloys such as lithium-indium, sodium-potassium, magnesium-silver, aluminum-lithium, aluminum-magnesium, and magnesium-indium. Metal oxide such as indium tin oxide (ITO) can also be used. These electrode substances can be used alone or in combination using the plurality of these electrode substances. The cathode can have a single layer structure or a multi-layer structure.

At least one of the anode and the cathode is preferably transparent or semi-transparent.

The substrate used in the present invention is not limited, but is an opaque substrate such as a metal substrate or a ceramic substrate, or a transparent substrate such as a substrate of glass, quartz or a plastic sheet. Luminescent light can be controlled by using a color filter coating, a fluorescent color conversion filter coating and a dielectric reflection coating or the like on the substrate. Further, the device can be prepared by connecting to the thin-film transistor (TFT) formed on the substrate.

Regarding the light extraction direction of the device can be any one of a bottom emission structure (structure for extracting light from the substrate side) and a top emission structure (structure extracting light from the side opposite to the substrate side).

A protective layer or a sealing layer for the purpose of preventing contact with oxygen and water can be disposed on the formed device. Examples of the protective layer are inorganic material films such as diamond thin film, metal oxide film and metal nitride film, polymer films such as films of fluorocarbon resins, polyparaxylene resins, polyethylene resins, silicon resins, and polystyrene resins, etc. and photo-curable resins. Further, packaging of the device can be prepared by using an appropriate sealing resin in combination of glass, a gas-impermeable film, a metal or the like.

The present invention will be specifically described with reference to the following Examples, but it is to be understood that the present invention is not limited to the following Examples.

### EXAMPLE 1

### Synthesis of Exemplified Compound A-48

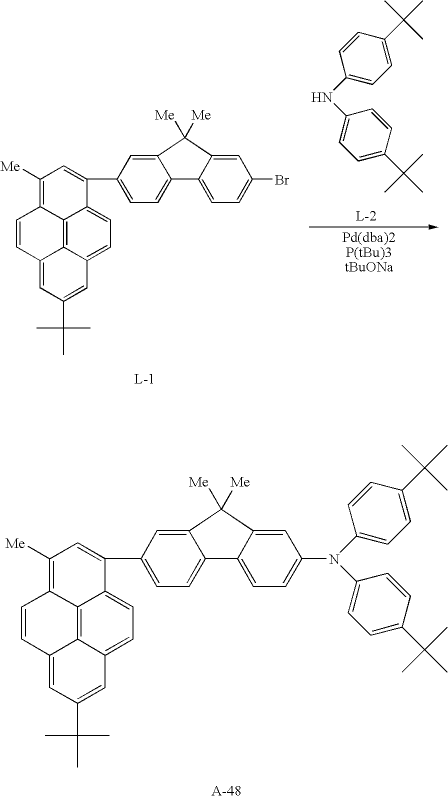

In a 200 ml-three necked flask, 0.924 g (1.70 mmol) of compound-L-1, 0.957 g (3.40 mmol) of compound L-2, 0.65 g (6.80 mmol) of sodium tert-butoxide and 100 ml of xylene were placed. 34.4 mg (0.17 mmol) of tri-tert-butyl phosphine was added thereto under nitrogen atmosphere at room temperature with stirring, and then 48.9 mg (0.085 mmol) of palladium dibenzylideneacetone was added thereto. The mixture was heated to 125° C. and stirred at 125° C. for 3 hours. The organic layer was extracted with toluene, dried on anhydrous sodium sulfate and purified by using silica gel column (developing solvent: mixture of heptane and toluene) to obtain 0.920 g of compound A-48 (yellowish white crystal) (yield: 72.7%).

The following data of the obtained compound were confirmed.

M⁺: 743.5 (mass spectrometry)

m.p.: 323° C. (DSC: differential scanning calorimetry)

### EXAMPLE 2

An organic light-emitting device having a structure as shown in FIG. 3 was produced by the following method.

On a glass substrate 1, a 120 nm-thick indium tin oxide (ITO) film as an anode 2 was formed by sputtering to prepare a transparent electroconductive support substrate. This was successively subjected to ultrasonic cleaning with acetone and isopropyl alcohol (IPA), in this order. The transparent electroconductive support substrate was then subjected to boiling cleaning with IPA and dried. Further it was subjected to UV/ozone cleaning, and was used as the transparent electroconductive support substrate.

The compound represented by the formula as shown below was used as a hole transport material, and a solution of the material in chloroform was prepared in a concentration of 0.1 wt %. This solution was added dropwise on the anode 2 of the transparent electroconductive support substrate, and spin coating was conducted at the beginning with rotation at 500 rpm for 10 seconds and subsequently at 1000 rpm for 1 minute to form a film. Thereafter, the film was dried in the vacuum oven at 80° C. for 10 minutes to completely remove the solvent in the thin film. The thickness of the formed hole transport layer was 11 nm.

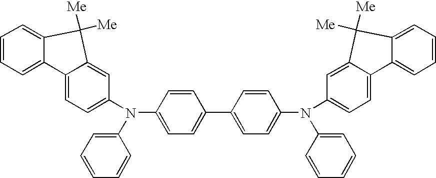

On the hole transport layer 5, the exemplified compound No. A-85 (the first compound) and the exemplified compound No. C-5 (the second compound) were co-deposited by vacuum deposition (weight ratio, 20:80) to form 40 nm-thick light emission layer 3. A vacuum degree at the vacuum deposition was 1.0×10⁻⁴ Pa and a deposition rate was 0.2 nm/sec or more and 0.3 nm/sec or less.

On the light emission layer 3, a 20 nm-thick electron transport layer 6 of basophenanthroline (BPhen) was formed by vacuum deposition. The vacuum degree at the evaporation was 1.0×10⁻⁴ Pa and a deposition rate was 0.2 nm/sec or more and 0.3 nm/sec or less.

Then, on the organic layer, using a deposition material consisting of aluminum-lithium alloy (lithium content: 1 atomic %), 0.5 nm-thick metal layer was formed by the vacuum deposition. Further, 150 nm-thick aluminum layer was formed by the vacuum deposition to produce the organic light-emitting device with the electron injection electrode (cathode 4) of an aluminum-lithium alloy layer. The vacuum degree at the deposition was 1.0×10⁻⁴ Pa and a deposition rate was 1.0 nm/sec or more and 1.2 nm/sec or less.

The produced organic EL device was covered by protection glass under dry air atmosphere in order not to deteriorate the device by adsorption of water and sealed with an acrylic resin adhesive.

To the thus produced organic light-emitting device, a voltage of 4.0V was applied between the ITO electrode (anode 2) as a positive electrode and the Al electrode (cathode 4) as a negative electrode, and blue luminescence having a central wavelength of 456 nm, a luminance of 3106 cd/m² and an emission efficiency of 3.8 lm/W was observed.

When the organic light-emitting device was supplied with a voltage for 100 hours while maintaining a current density of 30 mA/cm² under a nitrogen atmosphere, the initial luminance of 2400 cd/m² was decreased to 1980 cd/m² even after 100 hours of the voltage application, thus exhibiting small degradation of the luminance.

### COMPARATIVE EXAMPLE 1

An organic light-emitting device was prepared and evaluated in the same manner as in Example 1 except that the first compound C-5 was replaced by the comparative compound K-1 as shown below.

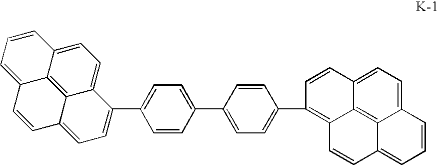

A voltage of 4.0 V was applied and the blue luminescence having a central wavelength of 444 nm, a luminance of 660 cd/m² and an emission efficiency of 1.1 lm/W was observed.

When the organic light-emitting device was supplied with a voltage for 100 hours while maintaining a current density of 30 mA/cm² under a nitrogen atmosphere, the initial luminance of 410 cd/m² was decreased to 160 cd/m² after 100 hours of the voltage application, thus exhibiting large degradation of the luminance.

### EXAMPLES 3 AND 4

Organic light-emitting devices were produced and evaluated in the same manner as in example 1 except that as the first compound and the second compound, compounds as shown in Table 13 were used, respectively. Results are shown in Table 13 and Table 14.

TABLE 13

| | First | Second | Applied | | | |
|---|---|---|---|---|---|---|
| | compound | compound | voltage | Luminance | Efficiency | Central |
| Example | No. | No. | (V) | (cd/m²) | (lm/W) | wavelength (nm) |
| 3 | A-32 | C-5 | 4 | 3533 | 4.1 | 460 |
| 4 | A-48 | C-11 | 4 | 2991 | 3.5 | 455 |

TABLE 14

Degradation of luminance

| | | After 100 hours |
|---|---|---|
| Example | Initial (cd/m²) | (cd/m²) |
| 3 | 2920 | 2290 |
| 4 | 2340 | 1860 |

### EXAMPLE 5

An organic light-emitting device was produced in the same manner as in Example 1 except that the exemplified compound No. A-90 was used as the first compound, the exemplified compound C-6 was used as the second compound, and 2,9-bis[2-(9,9-dimethylfluorenyl)]phenanethroline was used as the electron transport layer.

To the thus produced organic light-emitting device, a voltage of 4 V was applied between the ITO electrode (anode 2) as a positive electrode and the Al—Li electrode (cathode 4) as a negative electrode, and blue luminescence having a central wavelength of 457 nm, a luminance of 3580 cd/m² and an emission efficiency of 3.9 lm/W was observed.

When the organic light-emitting device was supplied with a voltage for 100 hours while maintaining a current density of 30 mA/cm² under a nitrogen atmosphere, the initial luminance of 2450 cd/m² was decreased to 1890 cd/m² even after 100 hours of the voltage application, thus exhibiting small degradation of the luminance.

### EXAMPLES 6 TO 9

Organic light-emitting devices were produced and evaluated in the same manner as in Example 5 except that as the first compound and the second compound, compounds as shown in Table 15 were used, respectively. Results are shown in Table 15 and Table 16.

TABLE 15

| | First | Second | Applied | | | |
|---|---|---|---|---|---|---|
| | compound | compound | voltage | Luminance | Efficiency | Central |
| Example | No. | No. | (V) | (cd/m²) | (lm/W) | wavelength (nm) |
| 6 | A-48 | C-5 | 4 | 3332 | 3.9 | 455 |
| 7 | A-74 | C-5 | 4 | 4096 | 4.4 | 458 |
| 8 | A-48 | C-11 | 4 | 3732 | 3.8 | 456 |
| 9 | A-32 | C-11 | 4 | 4200 | 4.4 | 460 |

TABLE 16

Degradation of luminance

| | | After 100 hours |
|---|---|---|
| Example | Initial (cd/m²) | (cd/m²) |
| 6 | 2760 | 2280 |
| 7 | 3260 | 2610 |
| 8 | 3100 | 2530 |
| 9 | 3620 | 2910 |

### EXAMPLE 10

An organic light-emitting device was produced in the same manner as in Example 5 except that the weight ratio of the first compound and the second compound was charged to 35:65.

To the thus produced organic light-emitting device, a voltage of 4 V was applied between the ITO electrode (anode 2) as a positive electrode and the Al—Li electrode (cathode 4) as negative electrode, and blue luminescence having a central wavelength of 457 nm, a luminance of 5115 cd/m² and an efficiency of 5.31 lm/W was observed.

When the organic light-emitting device was supplied with a voltage for 100 hours while maintaining a current density of 30 mA/cm² under a nitrogen atmosphere, the initial luminance of 3651 cd/m² was decreased to 3030 cd/m² even after 100 hours of the voltage application, thus exhibiting small degradation of the luminance.

### EXAMPLES 11 TO 13

Organic light-emitting devices were produced and evaluated in the same manner as in Example 10 except that as the first compound and the second compound, compounds as shown in Table 17 were used, respectively. Results are shown in Table 17 and Table 18.

TABLE 17

| | First | Second | Applied | | | |
|---|---|---|---|---|---|---|
| | compound | compound | voltage | Luminance | Efficiency | Central |
| Example | No. | No. | (V) | (cd/m²) | (lm/W) | wavelength (nm) |
| 11 | A-48 | C-5 | 4 | 5006 | 5.0 | 456 |
| 12 | A-85 | C-5 | 4 | 4705 | 4.7 | 455 |
| 13 | A-74 | C-11 | 4 | 5376 | 4.9 | 457 |

TABLE 18

Degradation of luminance

| | | After 100 hours |
|---|---|---|
| Example | Initial (cd/m²) | (cd/m²) |
| 11 | 4330 | 3530 |
| 12 | 4160 | 3240 |
| 13 | 4380 | 3660 |

### COMPARATIVE EXAMPLE 2

An organic light-emitting device was produced and evaluated in the same manner as in Example 10 except that the comparative compound No. K-2 as shown below was used as the first compound, the exemplified compound No. C-5 was used as the second compound, and then the both compounds were co-deposited to form 20 nm-thick light emission layer 3.

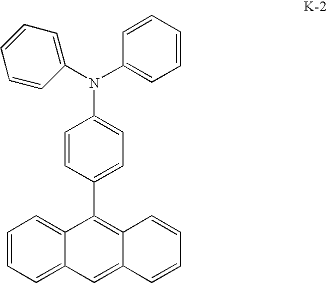

A voltage of 4.0 V was applied to the produced device, and the blue luminescence having a central wavelength of 468 nm, a luminance of 3800 cd/m² and an emission efficiency of 2.2 lm/W was observed.

When the organic light-emitting device was supplied with a voltage for 100 hours while maintaining a current density of 30 mA/cm² under a nitrogen atmosphere, the initial luminance of 2200 cd/m² was decreased to 555 cd/m² after 100 hours of the voltage application, thus exhibiting large degradation of the luminance.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims priority from Japanese Patent Application Nos. 2005-317935 filed Nov. 1, 2005, 2006-188155 filed Jul. 7, 2006, which are hereby incorporated by reference herein.

What is claimed is:

1. A fluorene compound represented by the following general formula (I): 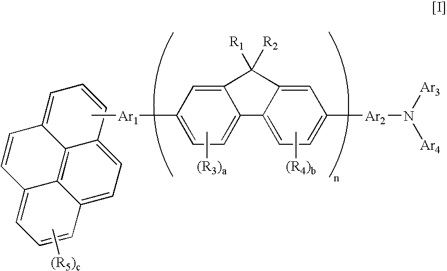
wherein R₁ to R₅ represent a substituted or unsubstituted alkyl group, aralkyl group, aryl group, heterocyclic group, amino group or cyano group, or a halogen atom; R₁ to R₅ may be the same or different; Ar₁ and Ar₂ represent a substituted or unsubstituted alkylene group, aralkylene group, arylene group or heterocyclic group or may be a direct single bond; Ar₁ and Ar₂ may be the same or different; Ar₃ and Ar₄ represent a substituted or unsubstituted phenyl group having at least one alkyl group having 2 or more carbon atoms at position 4; Ar₃ and Ar₄ may be the same or different; n represents an integer from 1 to 10; a and b represent an integer from 0 to 3; c represents an integer from 0 to 9; when a, b and c are an integer of 2 or more, each R₃, each R₄ and each R₅ may be the same or different; and when n is 2 or more, each R₁, each R₂, each R₃ and each R₄ on different fluorene groups may be the same or different.

2. The fluorene compound according to claim 1, wherein Ar₃ and Ar₄ are 4-tertiary-butylphenyl group.

3. The fluorene compound according to claim 1, wherein Ar₁ is a phenylene group or a direct single bond.

4. The fluorene compound according to claim 1, wherein the fluorene compound is represented by the following general formula (II):

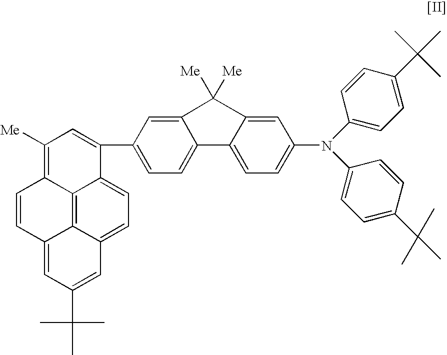

5. An organic light-emitting device comprising: a pair of electrodes consisting of an anode and a cathode, and one or more layers containing an organic compound, sandwiched between the pair of electrodes,
wherein at least one layer among the layers containing the organic compound contains at least one kind of a fluorene compound according to claim 1.

6. The organic light emitting device according to claim 5, wherein the layer containing the fluorene compound is a light emission layer.

7. An organic light-emitting device comprising: a pair of electrodes consisting of an anode and a cathode, and one or more of organic compound layers containing an organic compound, sandwiched between the pair of electrodes,
wherein at least one layer among the organic compound layers contains a first compound and a second compound,
the first compound is at least one kind of a fluorene compound represented by the following general formula (III): 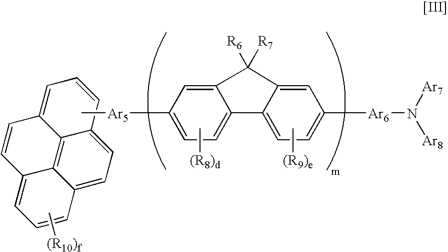
wherein R₆ to R₁₀ represent a substituted or unsubstituted alkyl group, aralkyl group, aryl group, heterocyclic group, amino group or cyano group, or a halogen atom; R₆ to R₁₀ may be the same or different; Ar₅ and Ar₆ represent a substituted or unsubstituted alkylene group, aralkylene group, arylene group or heterocyclic group or may be a direct single bond; Ar₅ and Ar₆ may be the same or different; Ar₇ and Ar₈ represent a substituted or unsubstituted alkyl group, aralkyl group, aryl group or heterocyclic group; Ar₇ and Ar₈ may be the same or different and may bind be linked together to form a ring; m represents an integer from 1 to 10; d and e represent an integer from 0 to 3; f represents an integer from 0 to 9; when d, e and f are an integer of 2 or more, each R₈, each R₉ and each R₁₀ may be the same or different; and when m is 2 or more, each R₆, each R₇, each R₈ and each R₉ on different fluorene groups may be the same or different; and
the second compound is at least one kind of a compound represented by the following general formula (IV): 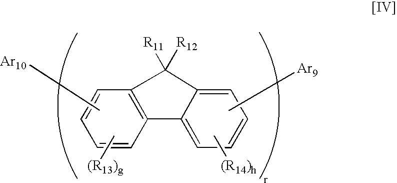
wherein R₁₁ and R₁₂ represent a hydrogen atom, an alkyl group, a substituted or unsubstituted aralkyl group, a substituted or unsubstituted aryl group, or a substituted or unsubstituted heterocyclic group; R₁₁ and R₁₂ may be the same or different; R₁₃ and R₁₄ represent a deuterium atom, an alkyl group, a substituted or unsubstituted aralkyl group, a substituted or unsubstituted aryl group, a substituted or a unsubstituted heterocyclic group, a substituted amino group, a cyano group or a halogen atom; R₁₃ and R₁₄ may be the same or different; Ar₉ and Ar₁₀ represent a substituted or unsubstituted pyrene; Ar₉ and Ar₁₀ may be the same or different; r represents an integer from 1 to 10; g and h represent an integer from 0 to 3; when g and h are an integer of 2 or more, each R₁₃ and each R₁₄ may be the same or different; and when r is 2 or more, each R₁₁, each R₁₂, each R₁₃ and each R₁₄ on different fluorene groups may be the same or different.

8. The organic light-emitting device according to claim 7, wherein Ar₃ and Ar₄ in the general formula (I) represent a substituted or unsubstituted phenyl group having at least one alkyl group having 2 or more carbon atoms at position 4.

9. The organic light-emitting device according to claim 7, wherein the first compound is a fluorene compound represented by the following general formula (II):

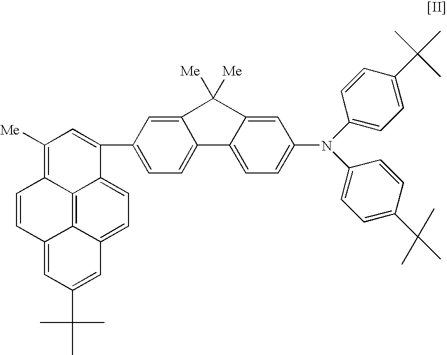

10. The organic light-emitting device according to claim 7, wherein the layer containing the first compound and the second compound is a light emission layer.
